(19) United States
(12) Patent Application Publication
(10) Pub. No.: US 2025/0089239 A1
(43) Pub. Date: Mar. 13, 2025

(54) SEMICONDUCTOR MEMORY DEVICE

(71) Applicant: Samsung Electronics Co., Ltd., Suwon-si (KR)

(72) Inventors: Sungmin PARK, Suwon-si (KR); Jinwoo HAN, Suwon-si (KR); Seokhan PARK, Suwon-si (KR); Gyuhwan OH, Suwon-si (KR); Bowon YOO, Suwon-si (KR)

(73) Assignee: Samsung Electronics Co., Ltd., Suwon-si (KR)

(21) Appl. No.: 18/804,207

(22) Filed: Aug. 14, 2024

(30) Foreign Application Priority Data
Sep. 8, 2023 (KR) 10-2023-0119816

(51) Int. Cl. H10B 12/00

(52) U.S. Cl. CPC H10B 12/482; H10B 12/315; H10B 12/488; H10B 12/50

(57) ABSTRACT

Provided is a semiconductor memory device including a plurality of word lines extending in a first horizontal direction, a plurality of channel patterns adjacent to a plurality of word line structures, arranged in a row in the first horizontal direction, and extending in a vertical direction, a plurality of bit lines extending in a second horizontal direction different from the first horizontal direction and electrically connected to a plurality of channel patterns, the plurality of word lines adjacent to the plurality of channel patterns, and the plurality of channel patterns on the bit lines, a shield conductive layer arranged below the plurality of bit lines and extending in the vertical direction between the bit lines, and a cover insulating layer arranged between the plurality of bit lines and the shield conductive layer. In a plan view the shield conductive layer comprises a main body unit and a pad unit, the plurality of bit lines overlapping the main body unit in the vertical direction, and a pad unit extending from the main body unit but the plurality of bit lines not overlapping the pad unit in the vertical direction.

### CROSS-REFERENCE TO RELATED APPLICATION

This application is based on and claims ranking under 35 U.S.C. § 119 to Korean Patent Application No. 10-2023-0119816, filed on Sep. 8, 2023 in the Korean Intellectual Property office, the disclosure of which is incorporated by reference herein in its entirety.

### BACKGROUND

The inventive concept relates to a semiconductor memory device. More particularly, the inventive concept relates to a semiconductor memory device including a vertical channel transistor.

As semiconductor memory devices become more highly integrated, semiconductor devices included in semiconductor memory devices also become highly integrated. Thus, to achieve high integration of semiconductor devices, vertical channel transistors may be vertically formed on semiconductor substrates, alternatively to planar channel transistors formed on the semiconductor substrates.

### SUMMARY

Various example embodiments of the inventive concepts provide a semiconductor memory device including a high-integration vertical channel transistor.

According to various aspects of the inventive concepts, there is provided a semiconductor memory device including a plurality of word lines extending in a first horizontal direction, a plurality of channel patterns adjacent to a plurality of word line structures, arranged in a row in the first horizontal direction, and extending in a vertical direction, a plurality of bit lines extending in a second horizontal direction different from the first horizontal direction and electrically connected to a plurality of channel patterns, the plurality of word lines adjacent to the plurality of channel patterns, and the plurality of channel patterns on the bit lines, a shield conductive layer arranged below the plurality of bit lines and extending in the vertical direction between the bit lines, and a cover insulating layer arranged between the plurality of bit lines and the shield conductive layer. In a plan view the shield conductive layer comprises a main body unit and a pad unit, the plurality of bit lines overlapping the main body unit in the vertical direction, and a pad unit extending from the main body unit but the plurality of bit lines not overlapping the pad unit in the vertical direction.

According to another aspect of the inventive concepts, there is provided a semiconductor memory device including a plurality of word lines extending in a first horizontal direction, a plurality of back gate lines extending in the first horizontal direction, and arranged apart from the plurality of word lines in a second horizontal direction different from the first horizontal direction, a plurality of channel patterns arranged between the word line and the back gate line adjacent to each other among the plurality of word lines and the plurality of back gate lines, and extending in a vertical direction, a plurality of bit lines extending in the second horizontal direction and electrically connected to the plurality of channel patterns, the plurality of bit lines are arranged below the plurality of word lines, and adjacent to the plurality of back gate lines, and the plurality of channel patterns, a shield conductive layer arranged below the plurality of bit lines and extending in the vertical direction between the bit lines, a shield contact connected to the shield conductive layer, a cover insulating layer arranged between the plurality of bit lines and the shield conductive layer, and a plurality of capacitor structures including a plurality of lower electrodes electrically connected to the plurality of channel patterns, an upper electrode on the plurality of lower electrodes, and a capacitor dielectric layer arranged between the plurality of lower electrodes and the upper electrode, wherein the shield conductive layer comprises a main body unit having a rectangular shape in a plan view, and a pad unit having a rectangular shape and extending from corner portions of the main body unit, and including the shield contact arranged on the shield conductive layer.

According to another aspect of the inventive concepts, there is provided a semiconductor memory device including a periphery circuit structure including a plurality of periphery circuits, on the periphery circuit structure, a plurality of word line structures including a plurality of word lines extending in a first horizontal direction and a plurality of gate insulating layers surrounding the plurality of word lines, on the periphery circuit structure, a plurality of back gate structures including a plurality of back gate lines arranged apart from the plurality of word lines in a second horizontal direction different from the first horizontal direction and extending in the first horizontal direction, and a plurality of back gate insulating layers covering the plurality of back gate lines, a plurality of channel patterns arranged in a row in the first horizontal direction and extending in a vertical direction, the plurality of channel patterns arranged between a word line structure and a back gate line adjacent to each other in the second horizontal direction among the plurality of word line structures and the plurality of back gate structures, a plurality of bit lines extending in the second horizontal direction and electrically connected to one end of the plurality of channel patterns, the plurality of bit lines arranged below the plurality of word line structures, the plurality of back gate lines, and the plurality of channel patterns, a shield conductive layer arranged below the plurality of bit lines and extending in the vertical direction between the bit lines, an uppermost portion of the shield conductive layer arranged opposite to the plurality of channel patterns, a shield contact connected to the shield conductive layer, a cover insulating layer arranged between the plurality of bit lines and the shield conductive layer, and a plurality of capacitor structures including a plurality of lower electrodes electrically connected to another end of the plurality of channel patterns in the vertical direction, an upper electrode on the plurality of lower electrodes, and a capacitor dielectric layer arranged between the plurality of lower electrodes and the upper electrode. The plurality of word lines, the plurality of bit lines, and the plurality of channel patterns constitute a plurality of vertical channel transistors. The shield conductive layer comprises a main body unit having a rectangular shape in a plan view, the plurality of bit lines and the plurality of word lines overlapping the main body unit in the vertical direction, and four pad units, each including the shield contact thereon and extending from an edge portion of the main body unit in a plan view, having a rectangular shape of less area than the main body unit, and not overlapping the plurality of bit lines and the plurality of word lines in the vertical direction.

### BRIEF DESCRIPTION OF THE DRAWINGS

Various example embodiments will be more clearly understood from the following detailed description taken in conjunction with the accompanying drawings in which:

FIGS. 1A through 1C are plan layouts of a semiconductor memory device, according to various example embodiments;

FIGS. 2A through 20D are cross-sectional views for describing a manufacturing method of a semiconductor memory device, according to various example embodiments, and FIGS. 21A through 21D are cross-sectional views of a semiconductor memory device, according to various example embodiments; and

FIGS. 22A through 22C are plan layouts of a semiconductor memory device according to various example embodiments.

### DETAILED DESCRIPTION OF THE DRAWINGS

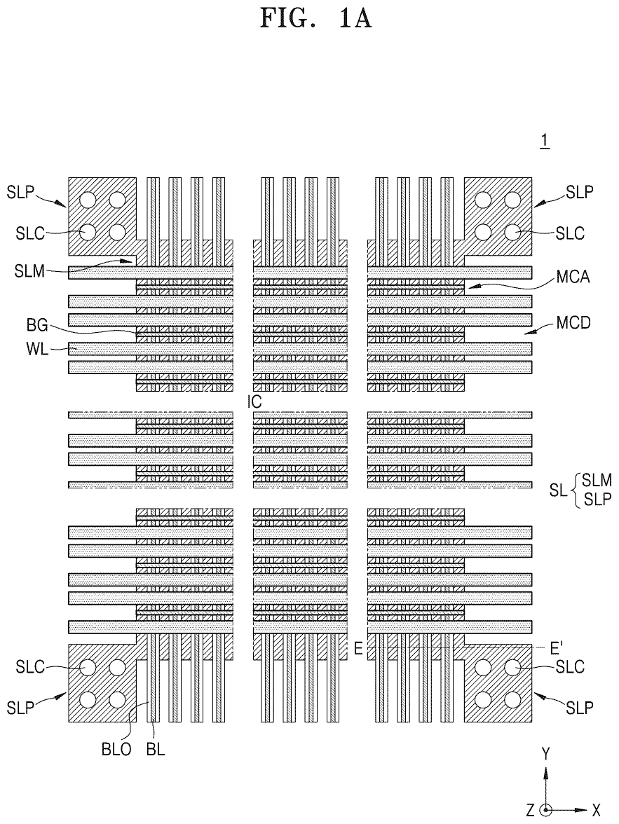

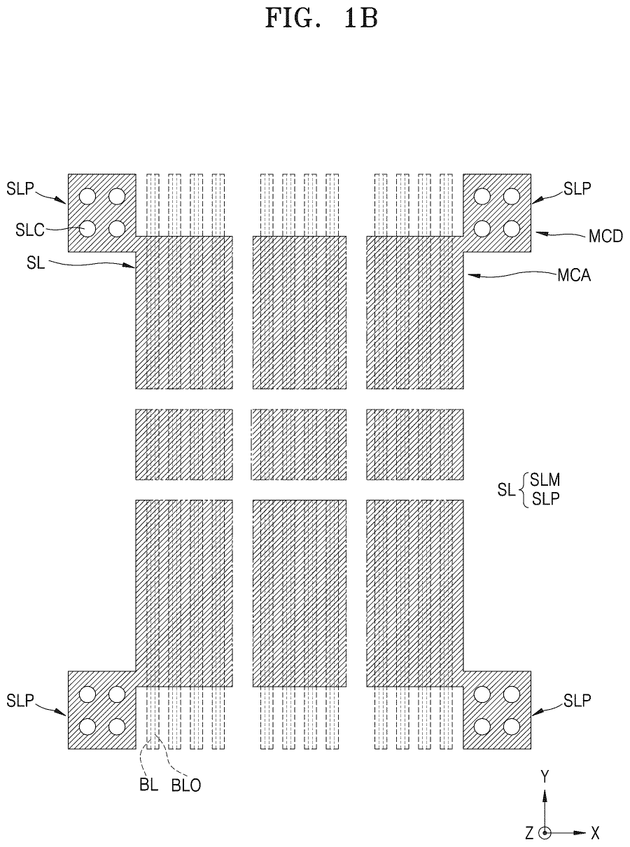

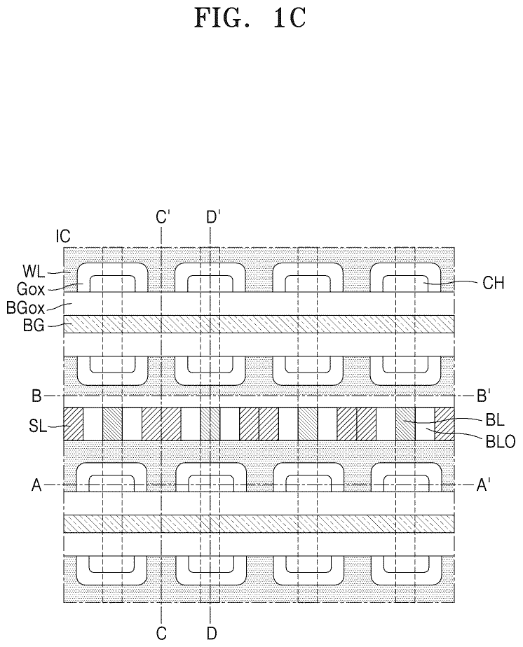

FIGS. 1A through 1C are plan layouts of a semiconductor memory device 1, according to various example embodiments. FIG. 1A is a plan layout of some components of the semiconductor memory device 1, FIG. 1B is a plan layout of a shield conductive layer included in the semiconductor memory device 1, and FIG. 1C is a detailed plan layout of an IC portion in FIG. 1A.

Referring to FIGS. 1A and 1B, the semiconductor memory device 1 may include a memory cell array region MCA and a dummy region MCD surrounding the memory cell array region MCA. The semiconductor memory device 1 may include a plurality of word lines WL extending in a first horizontal direction (X direction), a plurality of bit lines BL extending in a second horizontal direction (Y direction) that is different from the first horizontal direction (X direction), and a plurality of back gate lines BG extending in the first horizontal direction (X direction). The first horizontal direction (X direction) may be orthogonal to the second horizontal direction (Y direction). The memory cell array region MCA may include a region, in which the plurality of word lines WL and the plurality of bit lines BL cross each other, and the dummy region MCD may include a region, in which only the plurality of word lines WL are arranged or only the plurality of bit lines BL are arranged, as a region in which the word line WL and the plurality of bit lines BL are arranged not to cross each other.

The plurality of word lines WL and the plurality of back gate lines BG may be apart from each other in the second horizontal direction (Y direction) and may extend in parallel with each other in the first horizontal direction (X direction). Each of the plurality of back gate lines BG may be arranged between a pair of word lines WL adjacent to each other among the plurality of word lines WL. The number of word lines WL may be about two times the number of back gate lines BG. For example, two word lines WL among the plurality of word lines WL and one back gate line BG among the plurality of back gate lines BG may be alternately arranged in the second horizontal direction (Y direction).

The plurality of bit lines BL may be apart from each other in the first horizontal direction (X direction) and may extend in parallel with each other in the second horizontal direction (Y direction). A cover insulating layer BLO may surround the plurality of bit lines BL. The cover insulating layer BLO may be formed to conformally surround the sidewalls of the plurality of bit lines BL, and may not completely fill spaces between the plurality of bit lines BL. Shield conductive layers SL may include the cover insulating layer BLO therebetween, and surround the plurality of bit lines BL. Spaces between the plurality of bit lines BL, which have not been completely filled by the cover insulating layer BLO, may be filled by the shield conductive layer SL.

It is illustrated in FIG. 1A that the cover insulating layer BLO is arranged on both sides of each of the plurality of bit lines BL, and the shield conductive layer SL is arranged in plurality between two cover insulating layers BLO covering sidewalls facing each other of two adjacent plurality of bit lines BL, but the illustration is a conceptual diagram of a horizontal cross-section and not limited thereto. For example, the shield conductive layer SL and the cover insulating layer BLO, which are respectively shown in plurality in FIG. 1A, may be respectively connected to each other through lower ones of the plurality of bit lines BL to form one body.

A portion of the shield conductive layer SL arranged between two adjacent bit lines BL may have a line shape extending in the second horizontal direction (Y direction). Between two adjacent bit lines BL, a portion of the cover insulating layer BLO arranged between the bit line BL and the shield conductive layer SL may have a line shape in the second horizontal direction (Y direction). For example, a portion of one pair of cover insulating layers BLO, which are adjacent to each other in the first horizontal direction (X direction), extend in the second horizontal direction (Y direction), and have a line shape, may be arranged between the two adjacent bit lines BL.

The plurality of word lines WL may extend from the memory cell array region MCA to the dummy region MCD. For example, the plurality of word lines WL may extend from the memory cell array region MCA to the dummy region MCD on both sides of the memory cell array region MCA in the first horizontal direction (X direction). Both ends of the plurality of word lines WL may be at the portions of the dummy region MCD on both ends of the memory cell array region MCA in the first horizontal direction (X direction). Both ends of each of the plurality of word lines WL may be arranged in the second horizontal direction (Y direction) at each of the portions of the dummy region MCD at both ends of the memory cell array region MCA in the first horizontal direction (X direction).

The plurality of bit lines BL may extend from the memory cell array region MCA to the dummy region MCD. For example, the plurality of bit lines BL may extend from the memory cell array region MCA to the dummy region MCD on both sides of the memory cell array region MCA in the second horizontal direction (Y direction). Both ends of the plurality of bit lines BL may be at the portions of the dummy region MCD on both ends of the memory cell array region MCA in the second horizontal direction (Y direction). Both ends of each of the plurality of bit lines BL may be arranged in the first horizontal direction (X direction) at each of the portions of the dummy region MCD at both ends of the memory cell array region MCA in the second horizontal direction (Y direction).

The shield conductive layer SL may be overlapped with all of the memory cell array region MCA in a plan view. For example, the shield conductive layer SL may include a main body unit SLM arranged in the memory cell array region MCA, and a pad unit SLP extending from the main body unit SLM and arranged in the dummy region MCD. The main body unit SLM and the pad unit SLP may form one body. The main body unit SLM may have a rectangular shape corresponding to the memory cell array region MCA in a plan view. In a plan view, the pad unit SLP may extend from a corner portion of the main body unit SLM. In some example embodiments, the shield conductive layer SL may include four pad units SLP corresponding to one shield conductive layer SL. For example, the shield conductive layer SL may, in a plan view, include four pad units SLP extending from four corner portions of the main body unit SLM.

In a plan view, the pad unit SLP may have less area than the main body unit SLM. In some example embodiments, a plurality of shield contacts SLC may be arranged in the pad unit SLP. The plurality of shield contacts SLC may extend in a vertical direction (Z direction), and may be connected to the pad unit SLP of the shield conductive layer SL. For example, four to twenty five shield contacts SLC may be connected to each of four pad units SLP.

The pad unit SLP may have a rectangular shape in a plan view. In a plan view, among four edges of the pad unit SLP, one edge extending in the first horizontal direction (X direction) of two edges opposite to the main body unit SLM may be aligned with one end of each of the plurality of bit lines BL in the first horizontal direction (X direction). For example, one end of each of the plurality of bit lines BL may be aligned, in the first horizontal direction (X direction), with one edge extending in the first horizontal direction (X direction) of two edges opposite to the main body unit SLM of each of two pad units SLP among four pad units SLP, and the other end of each of the plurality of bit lines BL may be aligned, in the first horizontal direction (X direction), with one edge extending in the first horizontal direction (X direction) of two edges opposite to the main body unit SLM of each of the other two pad units SLP among four pad units SLP. In a plan view, among four edges of the pad unit SLP, the other edge extending in the second horizontal direction (Y direction) of two edges opposite to the main body unit SLM may be aligned with one end of each of the plurality of word lines WL in the second horizontal direction (Y direction). For example, one end of each of the plurality of word lines WL may be aligned, in the second horizontal direction (Y direction), with one edge extending in the second horizontal direction (Y direction) of two edges opposite to the main body unit SLM of each of two pad units SLP among four pad units SLP, and the other end of each of the plurality of word lines WL may be aligned, in the second horizontal direction (Y direction), with one edge extending in the second horizontal direction (Y direction) of two edges opposite to the main body unit SLM of each of the other two pad units SLP among four pad units SLP.

In a plan view, a distance between opposite edges of two pad units SLP aligned in the second horizontal direction (Y direction) among four pad units SLP may be the same as an extension length of the plurality of bit lines BL in the second horizontal direction (Y direction). In a plan view, a distance between opposite edges of two pad units SLP aligned in the first horizontal direction (X direction) among four pad units SLP may be the same as an extension length of the plurality of word lines WL in the first horizontal direction (X direction).

In some example embodiments, in a plan view, among four edges of the pad units SLP, one of two edges facing the main body unit SLM may be aligned with one of four edges of the main body unit SLM. It is illustrated in FIGS. 1A and 1B that, in a plan view, among four edges of the pad unit SLP, one edge extending in the second horizontal direction (Y direction) of two edges facing the main body unit SLM is aligned in the second horizontal direction (Y direction) with one edge extending in the second horizontal direction (Y direction) among four main body units SLM, but this is only an example and is not limited thereto. For example, in a plan view, among four edges of the pad unit SLP, one edge extending in the first horizontal direction (X direction) of two edges facing the main body unit SLM is aligned in the first horizontal direction (X direction) with one edge extending in the first horizontal direction (X direction) among four main body units SLM. Alternatively, in a plan view, all four edges of the pad unit SLP and all four edges of the main body unit SLM may not be aligned with each other in the first horizontal direction (X direction) or in the second horizontal direction (Y direction).

Portions adjacent to both ends of each of the plurality of word lines WL in the first horizontal direction (X direction), that is, portions arranged in the dummy region MCD, may not overlap the shield conductive layer SL, which includes the main body unit SLM and the pad unit SLP, in the vertical direction (Z direction). Portions adjacent to both ends of each of the plurality of bit lines BL in the second horizontal direction (Y direction), that is, portions arranged in the dummy region MCD, may not overlap the shield conductive layer SL, which includes the main body unit SLM and the pad unit SLP, in the vertical direction (Z direction). The main body unit SLM may overlap in the vertical direction (Z direction) with the remaining portions except for portions adjacent to both ends of the plurality of word lines WL in the first horizontal direction (X direction) and with the remaining portions except for portions adjacent to both ends of the plurality of bit lines BL, that is, portions arranged in the memory cell array region MCA among the plurality of word lines WL and the plurality of bit lines BL. The pad unit SLP may not overlap the plurality of word lines WL and the plurality of bit lines BL in the vertical direction (Z direction).

Referring to FIGS. 1A through 1C together, the semiconductor memory device 1 may include the plurality of word lines WL extending in the first horizontal direction (X direction), the plurality of bit lines BL extending in the second horizontal direction (Y direction), the plurality of back gate lines BG extending in the first horizontal direction (X direction), and a plurality of channel patterns CH extending in the vertical direction (Z direction).

The plurality of word lines WL and the plurality of back gate lines BG may be apart from each other in the second horizontal direction (Y direction) and may extend in parallel with each other in the first horizontal direction (X direction). Each of the plurality of back gate lines BG may be arranged between a pair of word lines WL adjacent to each other among the plurality of word lines WL. For example, two word lines WL and one back gate line BG may be alternately arranged in the second horizontal direction (Y direction).

The plurality of channel patterns CH may be arranged in a row in the first horizontal direction (X direction), between one word line WL and one back gate line BG, which are adjacent to each other, among the plurality of word lines WL and the plurality of back gate lines BG. The plurality of channel patterns CH may be arranged in a row in the second horizontal direction (Y direction). For example, each of the plurality of channel patterns CH arranged in one row in the second horizontal direction (Y direction) may be arranged between one word line WL and one back gate line BG adjacent to each other in the second horizontal direction (Y direction). For example, a pair of channel patterns CH including one back gate line BG among the plurality of back gate lines BG therebetween and being apart from each other in the second horizontal direction (Y direction) may have a line-symmetric shape with one back gate line BG as a reference.

Each of the plurality of channel patterns CH may include a first sidewall facing the back gate line BG and a second sidewall facing the word line WL and connected to an edge portion of the first sidewall. The first sidewall may have a plane and the second sidewall may have a curved surface. In other words, in a plan view, the first sidewall may have a linear shape, and the second sidewall may have a curved shape. For example, in a plan view, each of the plurality of channel patterns CH may have a rectangular shape, in which two corners facing the word line WL are rounded, or the second sidewall has an arc shape or an elliptical arc shape.

A gate insulating layer Gox may be arranged between the channel pattern CH and the word line WL, and a back gate insulating layer BGox may be arranged between the channel pattern CH and the back gate line BG. In some example embodiments, the gate insulating layer Gox may be formed to surround at least a portion of the channel pattern CH in a plan view. In some example embodiments, the back gate insulating layer BGox may extend in the first horizontal direction (X direction) along each side of the back gate line BG in the second horizontal direction (Y direction). The back gate insulating layer BGox may cover the first sidewall of the channel pattern CH, and the gate insulating layer Gox may cover the second sidewall. It is illustrated in FIG. 1C that in a plan view, the gate insulating layer Gox covers only the second sidewall of the channel pattern CH, but example embodiments are not limited thereto. For example, the gate insulating layer Gox may also be arranged between the first sidewall of the channel pattern CH and the back gate insulating layer BGox, to completely surround the channel pattern CH in a plan view.

The plurality of bit lines BL may be apart from each other in the first horizontal direction (X direction) and may extend in parallel with each other in the second horizontal direction (Y direction). The plurality of bit lines BL may extend in the second horizontal direction (Y direction), and may be electrically connected to the plurality of channel patterns CH. For example, the plurality of bit lines BL may be electrically connected to one end of the plurality of channel patterns CH in the vertical direction (Z direction). One bit line BL may be electrically connected to the channel pattern CH arranged in a row in the second horizontal direction (Y direction).

The bit line BL, the word line WL, the channel pattern CH adjacent to a portion of the word line WL crossing the bit line BL in a plan view, and the gate insulating layer Gox arranged between the word line WL and the channel pattern CH may constitute a vertical channel transistor.

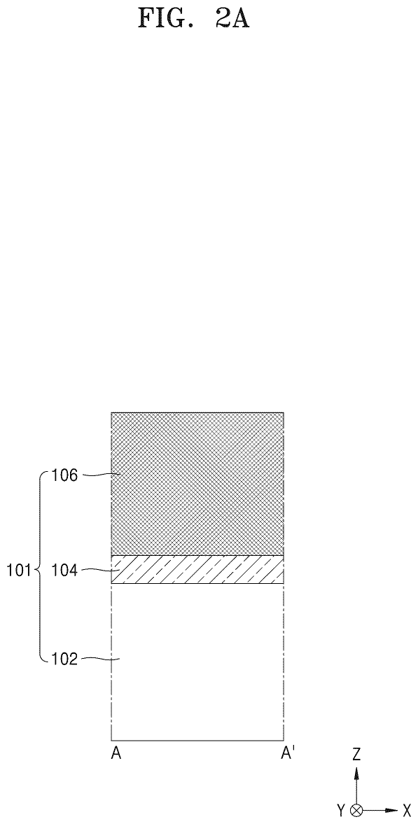

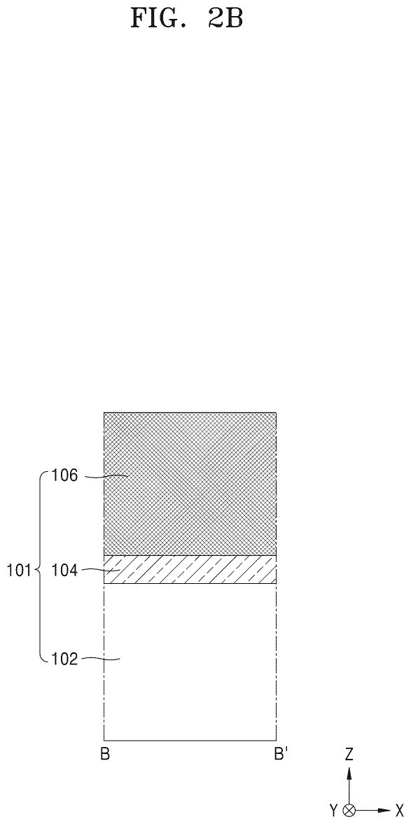

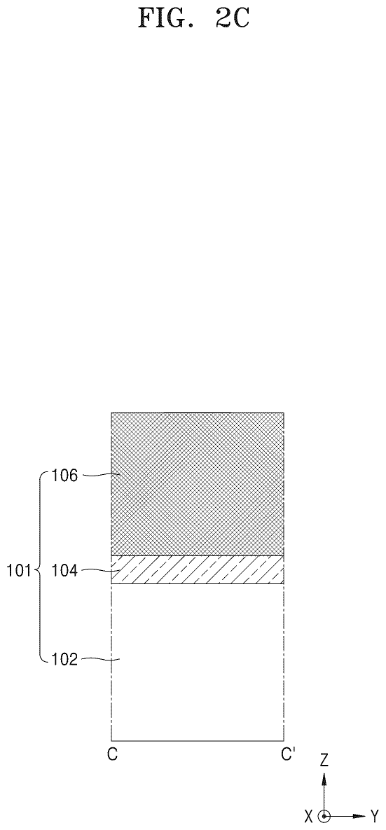

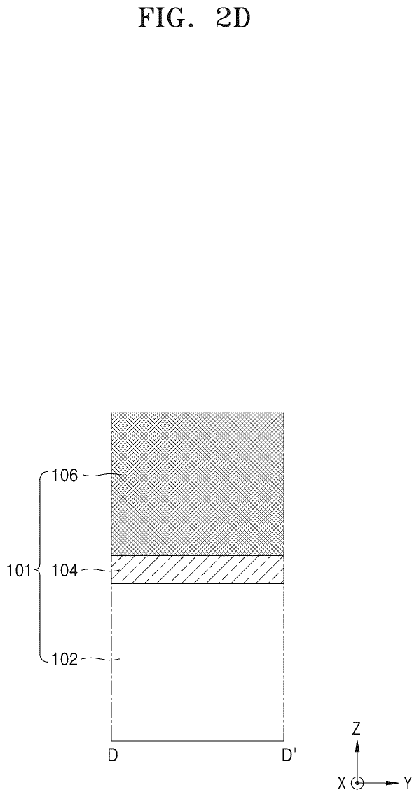

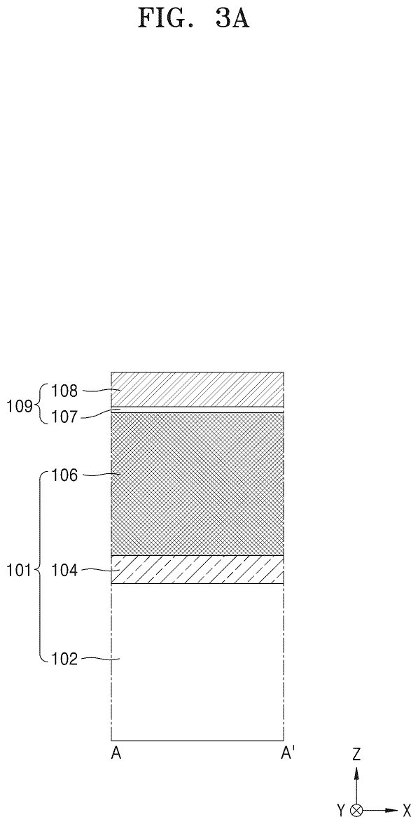

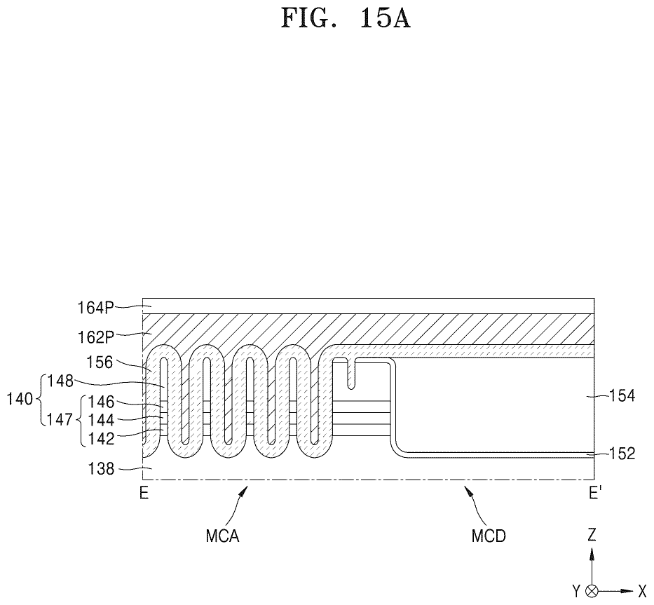

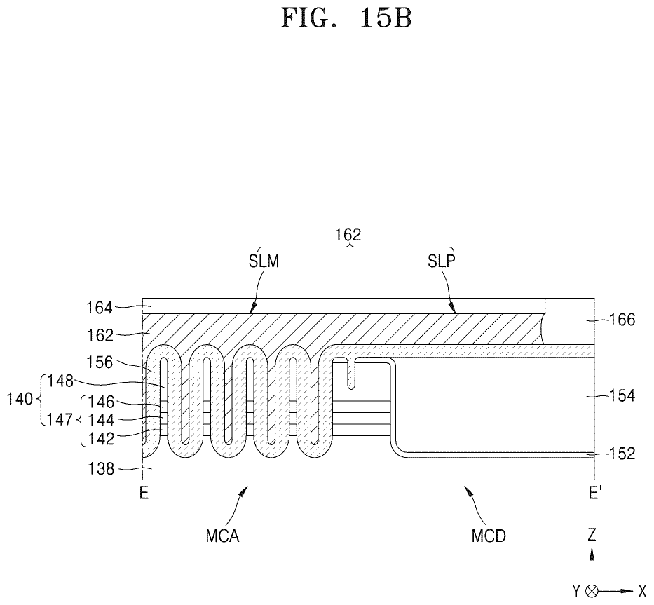

FIGS. 2A through 20D are cross-sectional views for describing a manufacturing method of a semiconductor memory device, according to various example embodiments, and FIGS. 21A through 21D are cross-sectional views of a semiconductor memory device, according to various example embodiments. FIGS. 2A, 3A, 4A, 5A, 6A, 7A, 8A, 9A, 10A, 11A, 12A, 13A, 14A, 16A, 17A, 18A, 19A, 20A, and 21A are cross-sectional views illustrating cross-sections taken along line A-A′ in FIG. 1A, FIGS. 2B, 3B, 4B, 5B, 6B, 7B, 8B, 9B, 10B, 11B, 12B, 13B, 14B, 16B, 17B, 18B, 19B, 20B, and 21B are cross-sectional views illustrating cross-sections taken along line B-B′in FIG. 1A, FIGS. 2C, 3C, 4C, 5C, 6C, 7C, 8C, 9C, 10C, 11C, 12C, 13C, 14C, 16C, 17C, 18C, 19C, 20C, and 21C are cross-sectional views illustrating cross-sections taken along line C-C′ in FIG. 1A, FIGS. 2D, 3D, 4D, 5D, 6D, 7D, 8D, 9D, 10D, 11D, 12D, 13D, 14D, 16D, 17D, 18D, 19D, 20D, and 21D are cross-sectional views illustrating cross-sections taken along line D-D′ in FIG. 1A, and FIGS. 15A and 15B are cross-sectional views illustrating cross-sections taken along line E-E′ in FIG. 1A.

Referring to FIGS. 2A through 2D, a substrate structure 101, in which a base substrate 102, a base insulating layer 104, and a channel pattern 106 are sequentially stacked, may be prepared. In some example embodiments, the substrate structure 101, in which the base substrate 102, the base insulating layer 104, and the channel pattern 106 are sequentially stacked, may include at least one of a silicon-on-insulator (SOI) substrate or a germanium-on-insulator (GeOI) substrate. The base substrate 102 may include a semiconductor material. For example, the base substrate 102 may include a semiconductor element, such as at least one of silicon (Si) and germanium (Ge) or may include at least one compound semiconductor of silicon germanium (SiGe), silicon carbide (SiC), gallium arsenide (GaAs), indium arsenide (InAs), and indium phosphide (InP). However, example embodiments are not limited thereto. The base insulating layer 104 may include silicon oxide. In some example embodiments, the channel pattern 106 may include a semiconductor material. For example, the channel pattern 106 may include monocrystalline silicon or polysilicon. In some other example embodiments, the channel pattern 106 may include an oxide semiconductor material. However, example embodiments are not limited thereto. The channel pattern 106 may include at least one of a binary or ternary oxide semiconductor material including a first metal element, a ternary oxide semiconductor material including different first and second metal elements from each other, and a quaternary oxide semiconductor material including different first, second, and third metal elements from each other.

The binary or ternary oxide semiconductor material may include, for example, at least one of zinc oxide (ZnO, ZnₓO), gallium oxide (GaO, GaxO), tin oxide (TiO, TiₓO), zinc oxide (ZnON, ZnₓO_{y}N), indium zinc oxide (IZO, InₓZn_{y}O), gallium zinc oxide (GZO, GaₓZn_{y}O), tin zinc oxide (TZO, SnₓZn_{y}O), and tin gallium oxide (TGO, SnₓGa_{y}O), but is not limited thereto. The quaternary oxide semiconductor material may include any one of indium gallium zinc oxide (IGZO, InₓGa_{Y}Zn_{z}O), indium gallium silicon oxide (IGSO, InₓGa_{y}Si,O), indium tin zinc oxide (ITZO, InₓSn_{Y}Zn_{z}O), indium gallium tin oxide (IGTO, InₓGa_{y}Sn_{z}O), zirconium zinc tin oxide (ZZTO, ZrₓZn_{y}Sn_{z}O), hafnium indium zinc oxide (HIZO, HfₓIn_{Y}Zn_{z}O), gallium zinc tin oxide (GZTO, Ga_{X}Zn_{y}Sn_{z}O), aluminum zinc tin oxide (AZTO, Al_{X}Zn_{y}Sn_{z}O), ytterbium gallium zinc oxide (YGZO, YbₓGa_{Y}Zn_{z}O), and indium aluminum zinc oxide (IAZO), but example embodiments are not limited thereto.

In some example embodiments, the channel pattern 106 may include a crystalline oxide semiconductor material or an amorphous oxide semiconductor material. When the channel pattern 106 includes a crystalline oxide semiconductor material, the channel pattern 106 may have at least one crystalline of single crystalline, polycrystalline, spinel, and c-axis aligned crystalline (CAAC). However, example embodiments are not limited thereto. In some example embodiments, the channel pattern 106 may include at least two stacked layers including a first layer including a crystalline oxide semiconductor material and a second layer including an amorphous oxide semiconductor material. For example, the channel pattern 106 may include the first layer including a crystalline oxide semiconductor material, the second layer including an amorphous oxide semiconductor material, and a third layer including a crystalline oxide semiconductor material, which are sequentially stacked.

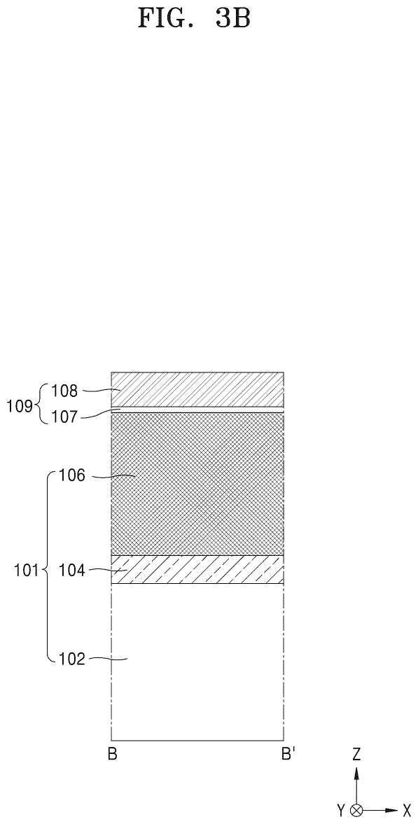

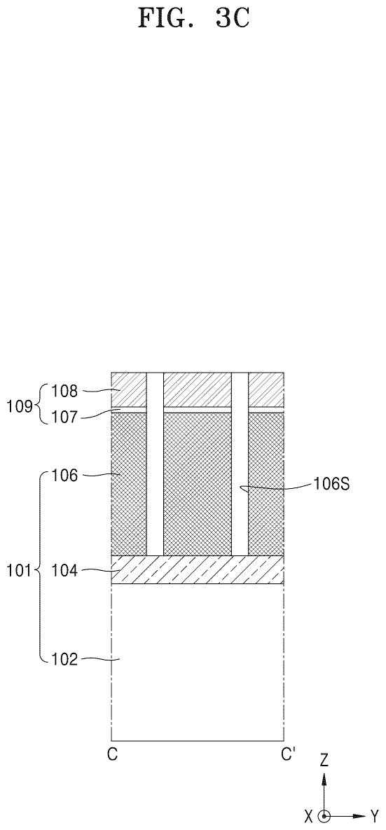

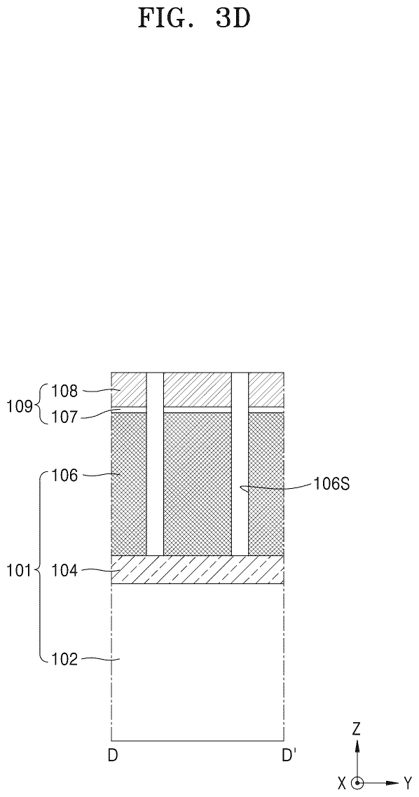

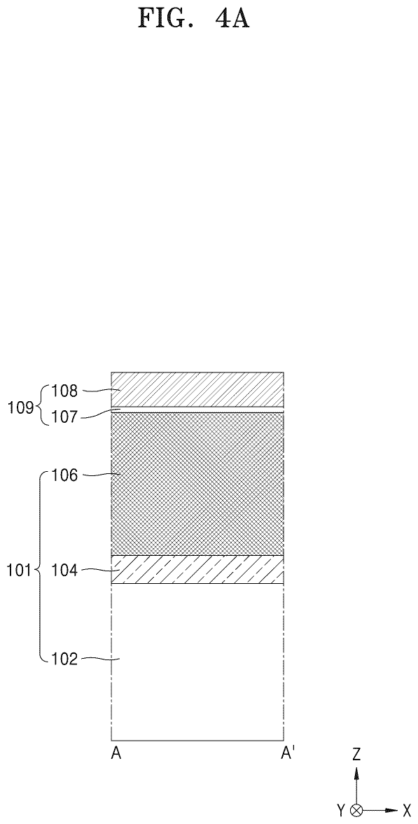

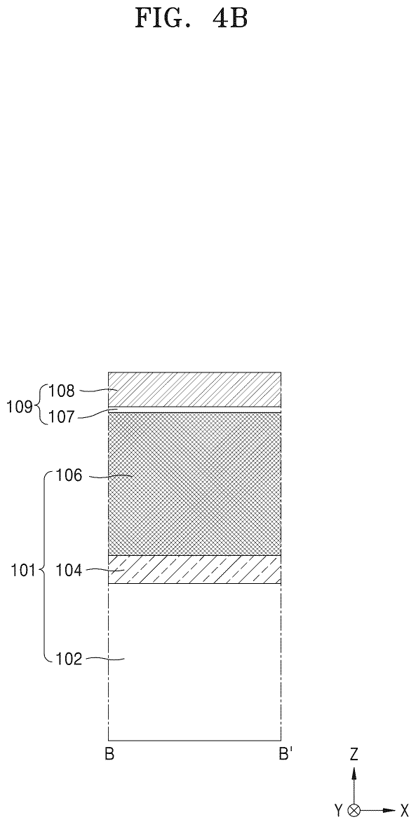

Referring to FIGS. 3A through 3D, a plurality of first mask patterns 109 may be formed on the channel pattern 106. In some example embodiments, the plurality of first mask patterns 109 may be formed to extend in parallel with each other in the first horizontal direction (X direction). The channel pattern 106 may be divided into a plurality by removing portions of the channel pattern 106 by using the plurality of first mask patterns 109 as an etching mask. The base insulating layer 104 may be exposed on lower surfaces of spaces where the portions of the channel pattern 106 have been removed. In some example embodiments, the channel pattern 106, which has been divided into a plurality, may extend in parallel with each other in the first horizontal direction (X direction). A plurality of inter-channel spaces 106S may be limited between the divided plurality of channel patterns 106. The plurality of inter-channel spaces 106S may extend in parallel with each other in the first horizontal direction (X direction).

In some example embodiments, each of the plurality of first mask patterns 109 may have a stacked structure including a lower mask pattern 107 and an upper mask pattern 108. For example, the lower mask pattern 107 may include oxide, and the upper mask pattern 108 may include nitride.

Referring to FIGS. 3A though 3D and 4A through 4D together, a plurality of base insulating structures 113 filling lower side portions of the plurality of inter-channel spaces 106S, which are spaces between the divided plurality of channel patterns 106, may be formed. The plurality of base insulating structures 113 may be formed to extend in parallel with each other in the first horizontal direction (X direction).

In some example embodiments, each of the plurality of base insulating structures 113 may have a stacked structure including a lower insulating layer 111 and an upper insulating layer 112. For example, the lower insulating layer 111 may include oxide, and the upper insulating layer 112 may include nitride. The lower insulating layer 111 may conformally cover the lower side portions and lower surfaces of inner sidewalls of the inter-channel space 106S. The upper insulating layer 112 may be formed to fill a space limited by the lower insulating layer 111. For example, after sequentially forming a preliminary lower insulating layer conformally covering the surface of the base insulating layer 104 and the surface of the inter-channel space 106S exposed on the inner sidewalls and lower surface of the inter-channel space 106S, and side surfaces of an upper surface of the plurality of first mask patterns 109, and a preliminary upper insulating layer covering the preliminary lower insulating layer and filling all of the inter-channel spaces 106S, the base insulating structure 113 may be formed by removing an upper portion of each of the preliminary lower insulating layer and the preliminary upper insulating layer. For example, the lower insulating layer 111 and the upper insulating layer 112 may include a portion of the preliminary lower insulating layer filling the lower side portion of the inter-channel space 106S and a portion of the preliminary upper insulating layer, respectively.

By removing a portion of a plurality of channel patterns 106 exposed via the plurality of inter-channel spaces 106S, the lower side portion of which is filled by the plurality of base insulating structures 113, a plurality of expanded inter-channel spaces 106SE may be formed. Each of the plurality of expanded inter-channel spaces 106SE may include a space, where the upper side portion of the inter-channel space 106S is not filled by the base insulating structure 113 and portions of the channel pattern 106 are removed.

Thereafter, a plurality of back gate structures BGS each including a back gate insulating layer 114 covering a lower surface and inner sidewalls of each of the plurality of expanded inter-channel spaces 106SE, a back gate line 116 on the back gate insulating layer 114, and a back gate capping layer 118 on the back gate line 116 may be formed. A plurality of back gate insulating layers 114 may be formed to cover the lower surfaces and the inner sidewalls of the plurality of expanded inter-channel spaces 106SE but not to fill all of the plurality of expanded inter-channel spaces 106SE, a plurality of back gate lines 116 may be formed to cover the plurality of back gate insulating layers 114 but not to fill all of the plurality of expanded inter-channel spaces 106SE, and a plurality of back gate capping layers 118 may be formed to fill all of the plurality of expanded inter-channel spaces 106SE. In some example embodiments, the back gate insulating layer 114 may be formed thicker on a surface of the channel pattern 106 than on side surfaces of a first mask pattern 109, in response to a space formed by removing a portion of the channel pattern 106.

The back gate insulating layer 114 may include at least one of silicon oxide, silicon nitride, silicon oxynitride, oxide-nitride-oxide (ONO), and high-k dielectrics having a higher dielectric constant than silicon oxide. However, example embodiments are not limited thereto. For example, the back gate insulating layer 114 may have a dielectric constant of about 10 to about 25. The back gate line 116 may include a semiconductor material, a metal material, a conductive metal nitride, or a combination thereof. In some example embodiments, the back gate line 116 may include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof. However, example embodiments are not limited thereto. The back gate capping layer 118 may include silicon oxide.

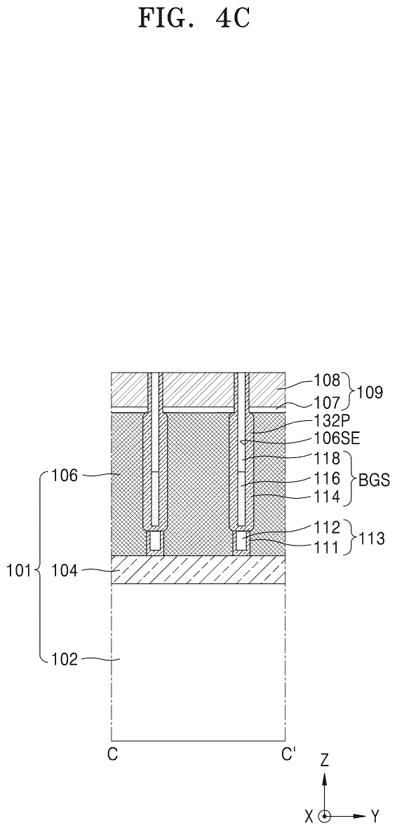

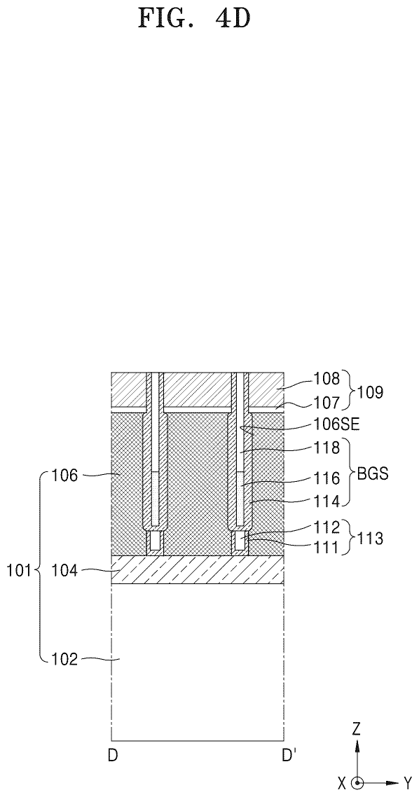

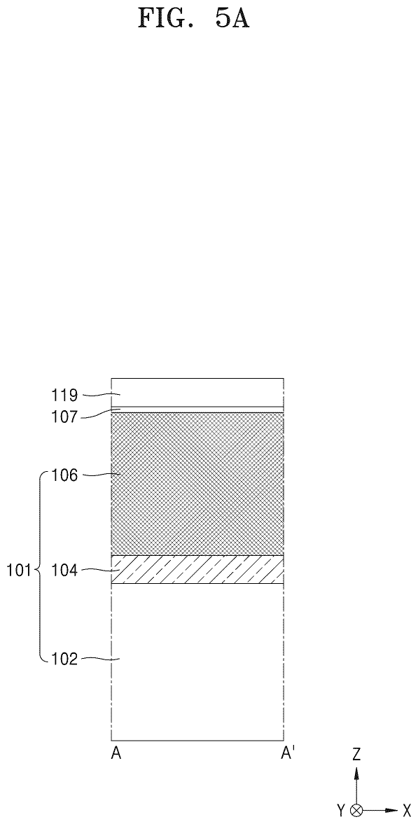

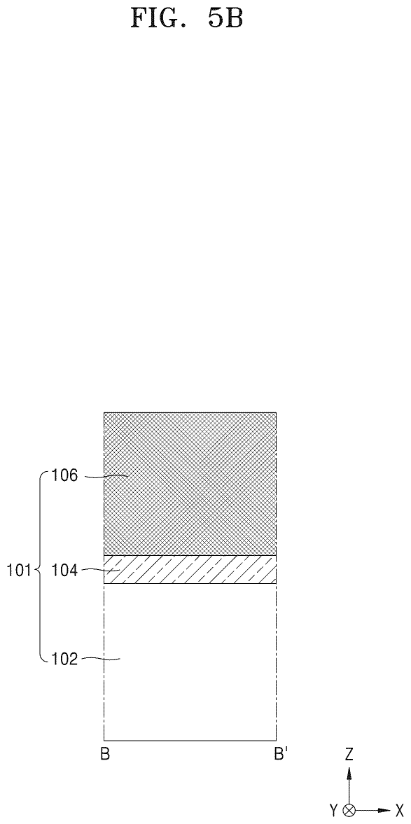

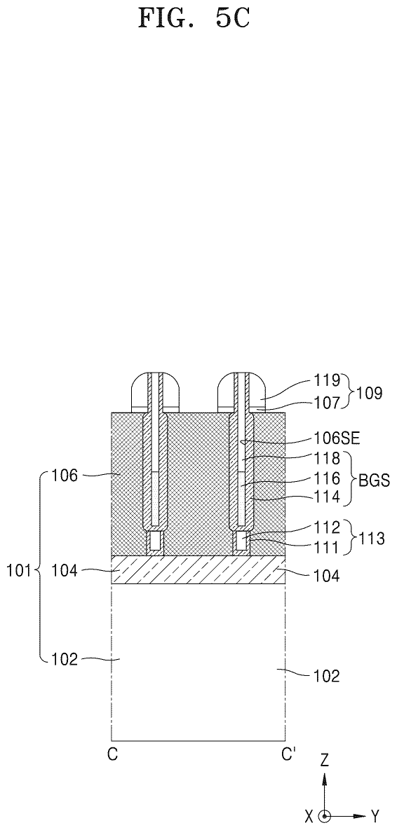

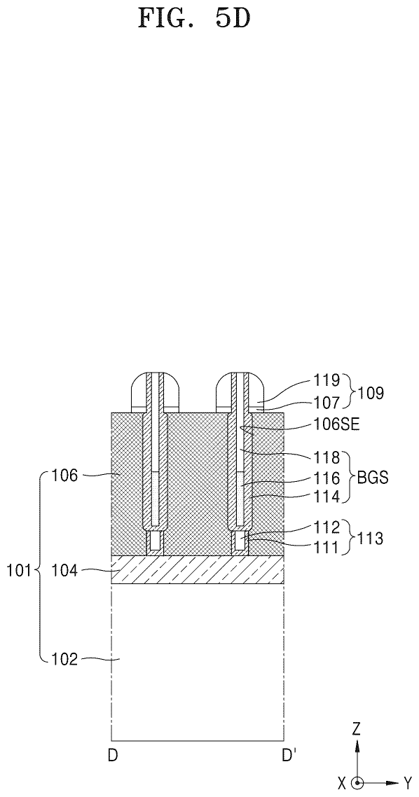

Referring to FIGS. 4A through 4D and 5A through 5D together, after the upper mask pattern 108 is removed, and a preliminary spacer material layer covering the plurality of back gate structures BGS exposed on the lower mask pattern 107 is formed, and by removing a portion of the preliminary spacer material layer, a plurality of insulating spacers 119 covering both side surfaces of the plurality of back gate structures BGS may be formed. For example, the plurality of back gate structures BGS may be formed by using an anisotropic etching process such as an etch-back process and removing a portion of the preliminary spacer material layer. In a process of forming the plurality of insulating spacers 119, a portion of the lower mask pattern 107, which is not covered by the plurality of insulating spacers 119, may also be removed, and the upper surface of the plurality of channel patterns 106 may be exposed. The remaining portions of the lower mask pattern 107, which has not been removed but has remained, may be arranged under the plurality of insulating spacers 119.

The plurality of insulating spacers 119 may include oxide. For example, the plurality of insulating spacers 119 may include silicon oxide. The plurality of insulating spacers 119 may be formed to extend in parallel with each other in the first horizontal direction (X direction).

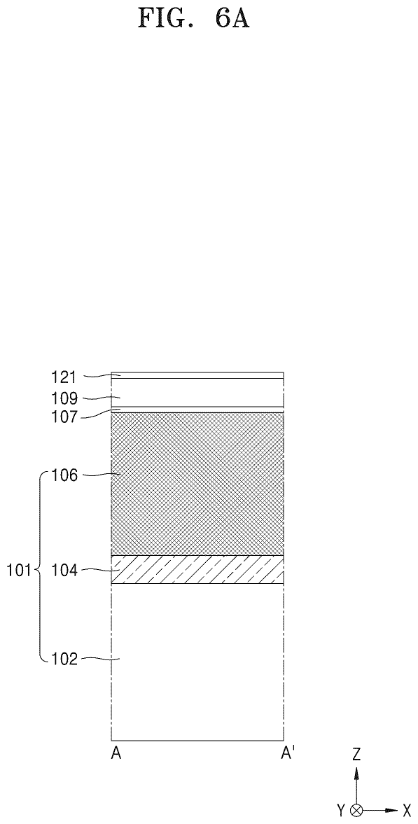

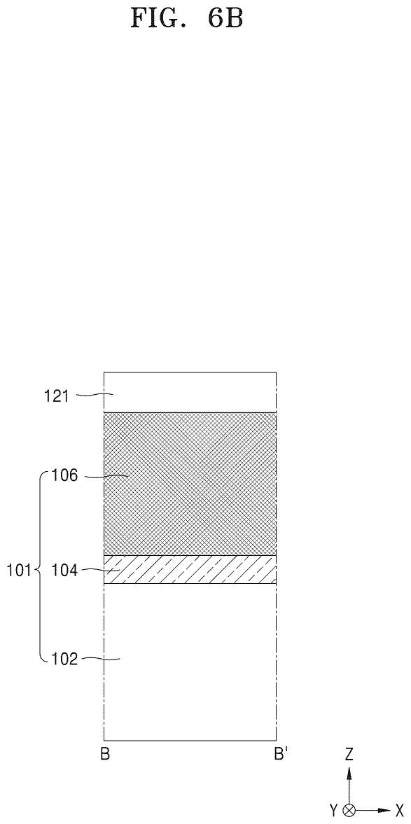

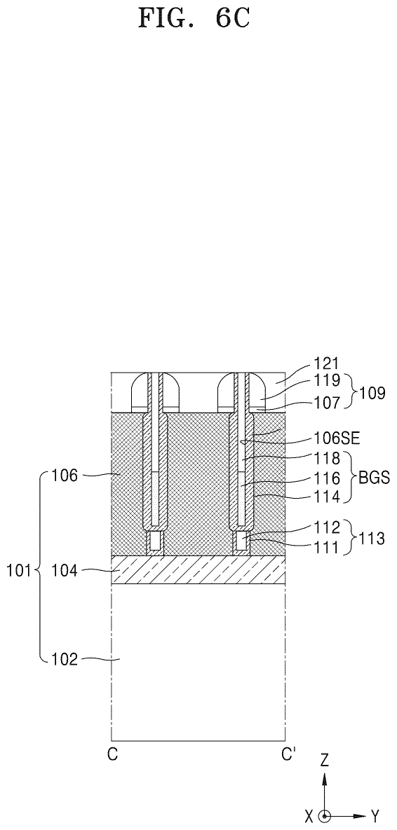

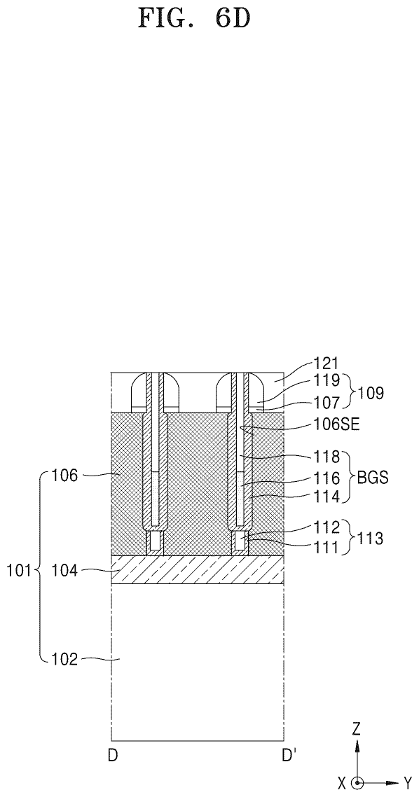

Referring to FIGS. 6A through 6D, a mold layer 121 covering the plurality of insulating spacers 119 may be formed. After a preliminary mold layer covering the plurality of insulating spacers 119 and the plurality of back gate structures BGS are formed, the mold layer 121 may be formed by removing a portion of the preliminary mold layer so that the plurality of back gate structures BGS are exposed. For example, the mold layer 121 may include polysilicon.

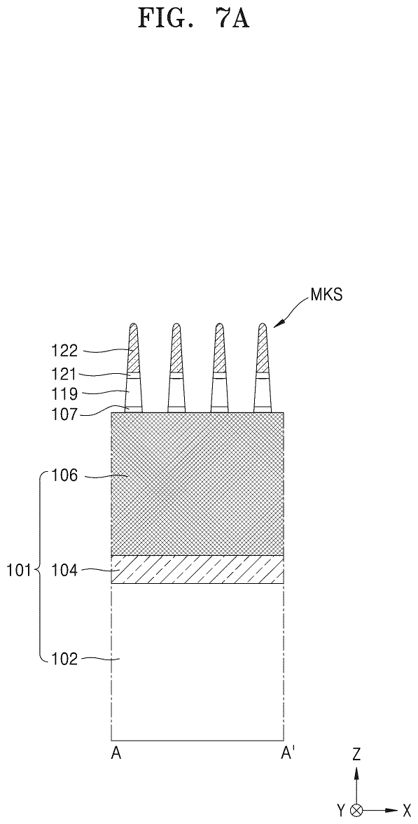

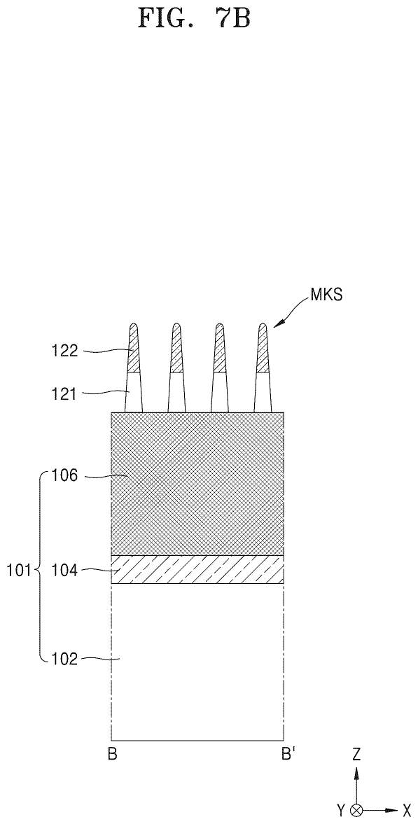

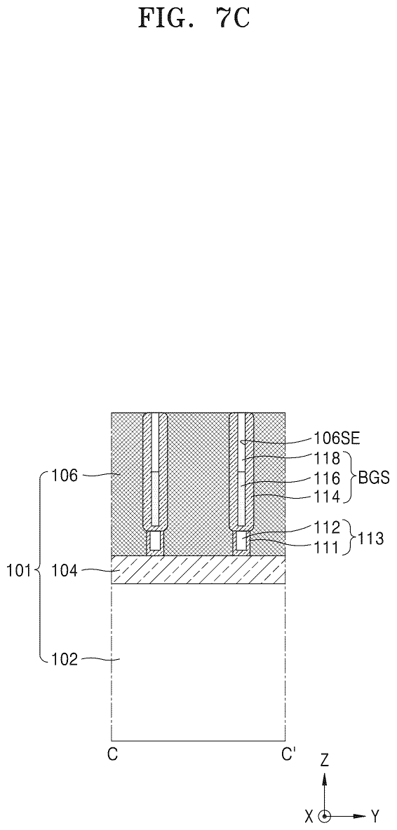

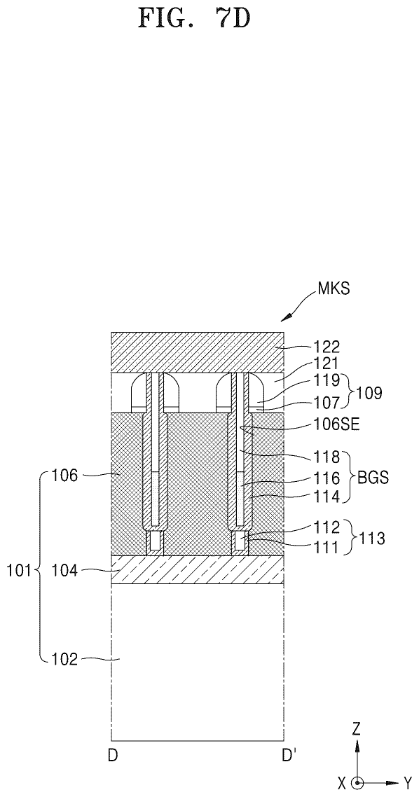

Referring to FIGS. 7A through 7D together, a plurality of second mask patterns 122 may be formed on the mold layer 121 and the plurality of back gate structures BGS. In some example embodiments, the plurality of second mask patterns 122 may be formed to extend in parallel with each other in the second horizontal direction (Y direction). The plurality of second mask patterns 122 may include a carbon-based layer. For example, the carbon-based layer may include at least one of an amorphous carbon layer (ACL) or a carbon-based spin-on hardmask (C-SOH) layer. However, example embodiments are not limited thereto. By removing a portion of each of the mold layer 121, the plurality of insulating spacers 119, the plurality of back gate structures BGS, and the lower mask pattern 107 by using the plurality of second mask patterns 122 as etching masks, a plurality of mask structures MKS including the plurality of second mask patterns 122, the remaining mold layer 121, the plurality of insulating spacers 119, the plurality of back gate structures BGS, and the lower mask pattern 107 may be formed. The plurality of mask structures MKS may, similar to the plurality of second mask patterns 122, be formed to extend in parallel with each other in the second horizontal direction (Y direction). Portions of the plurality of channel patterns 106 may be exposed on lower surfaces of spaces between the plurality of mask structures MKS.

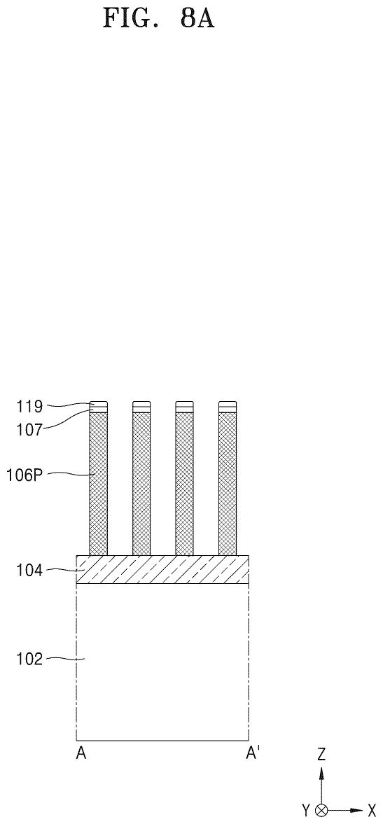

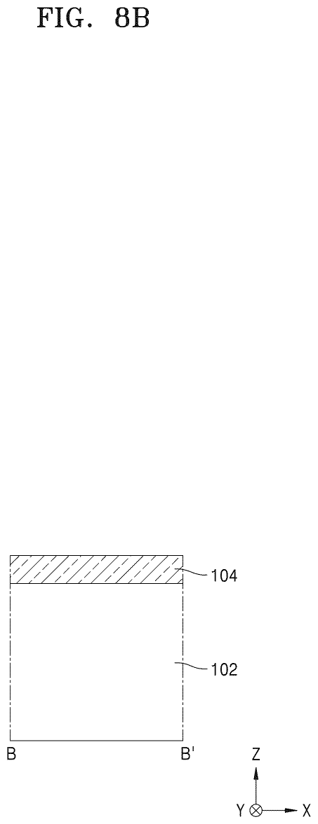

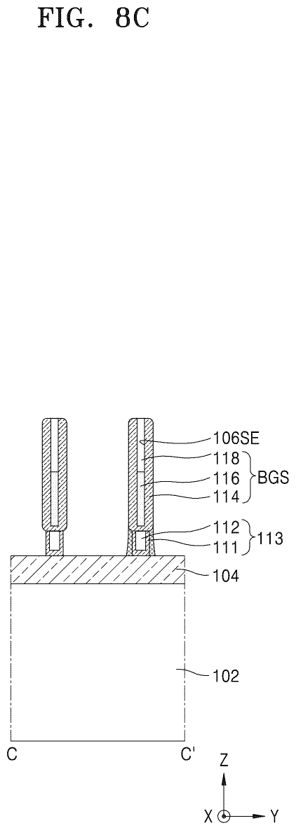

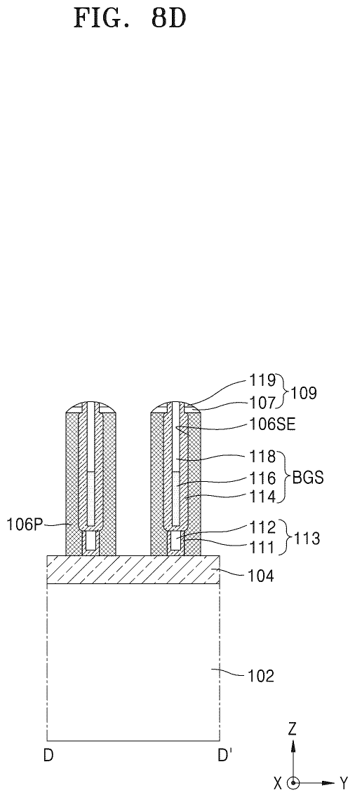

Referring to FIGS. 7A through 7D and 8A through 8D together, a plurality of channel patterns 106P may be formed by patterning the plurality of channel patterns 106 by using the plurality of mask structures MKS as etching masks. In the process of forming the plurality of channel patterns 106P, the plurality of second mask patterns 122 among the plurality of mask structures MKS may all be etched and removed. After the plurality of second mask patterns 122 are removed, an etching process on the mold layer 121 and the plurality of channel patterns 106 may be performed by using the plurality of insulating spacers 119 and the plurality of back gate structures BGS as etching masks to remove all of the mold layer 121, and the plurality of channel patterns 106P may be formed.

The plurality of channel patterns 106P may be arranged in a row along both side surfaces of the plurality of back gate structures BGS in the first horizontal direction (X direction). A portion of the lower mask pattern 107 and a portion of the plurality of insulating spacers 119 may remain on the plurality of channel patterns 106P.

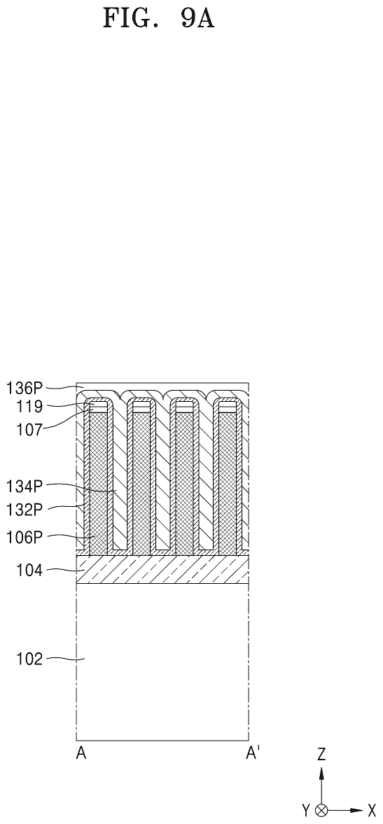

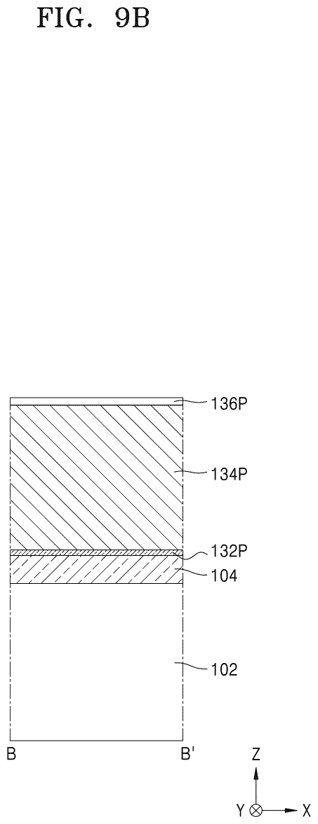

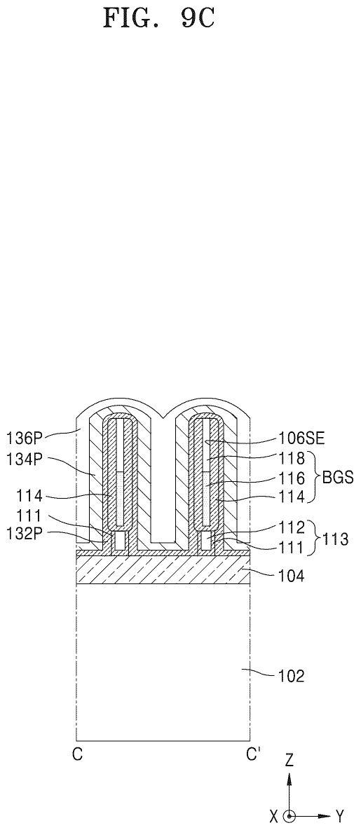

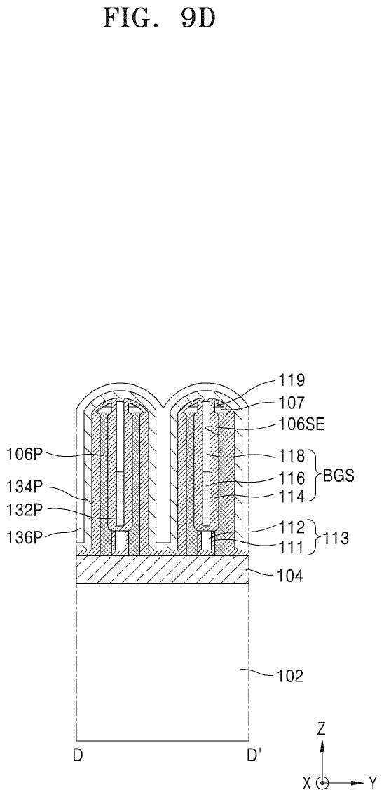

Referring to FIG. 9A through 9D together, a preliminary gate insulating layer 132P, a preliminary word line layer 134P, and a preliminary separation insulating layer 136P, which sequentially covers the plurality of channel patterns 106P and the plurality of back gate structures BGS, may be formed. The preliminary gate insulating layer 132P may be formed to conformally cover the plurality of channel patterns 106P and the plurality of back gate structures BGS. The preliminary word line layer 134P may be formed to cover the preliminary gate insulating layer 132P and fill all spaces between the plurality of channel patterns 106P adjacent to the preliminary word line layer 134P, but not fill all spaces between the plurality of back gate structures BGS adjacent to each other in the second horizontal direction (Y direction). The preliminary separation insulating layer 136P may be formed to cover the preliminary word line layer 134P and fill all spaces between the plurality of back gate structures BGS adjacent to the preliminary separation insulating layer 136P in the second horizontal direction (Y direction).

The preliminary gate insulating layer 132P may include at least one of silicon oxide, silicon nitride, silicon oxynitride, ONO, and high-k dielectrics having a higher dielectric constant than silicon oxide. However, example embodiments are not limited thereto. For example, the preliminary gate insulating layer 132P may have a dielectric constant of about 10 to about 25. A word line 134 may include a semiconductor material, a metal material, a conductive metal nitride, or a combination thereof. In some example embodiments, the preliminary word line layer 134P may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof. However, example embodiments are not limited thereto. The preliminary separation insulating layer 136P may include silicon oxide.

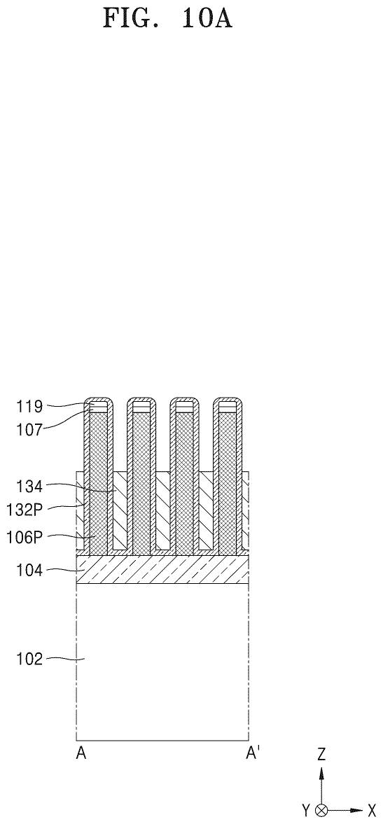

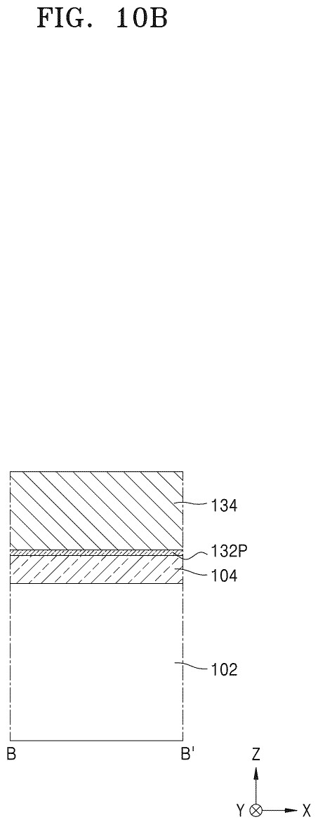

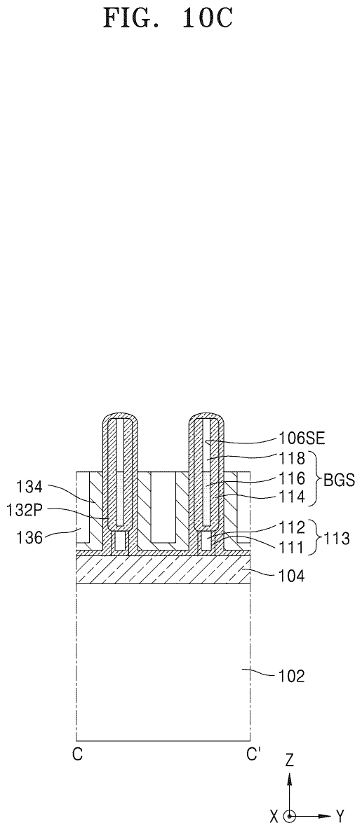

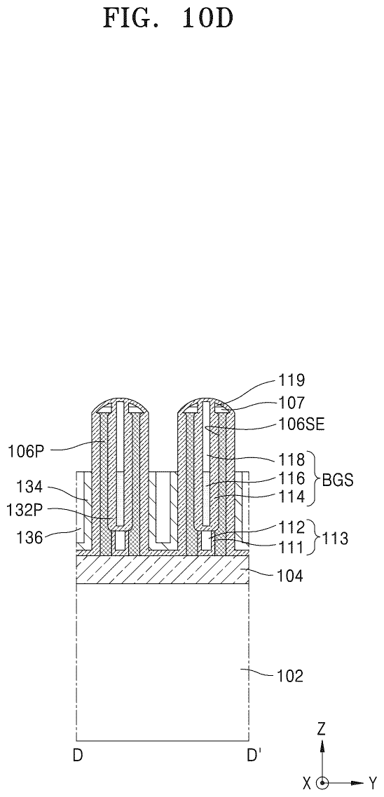

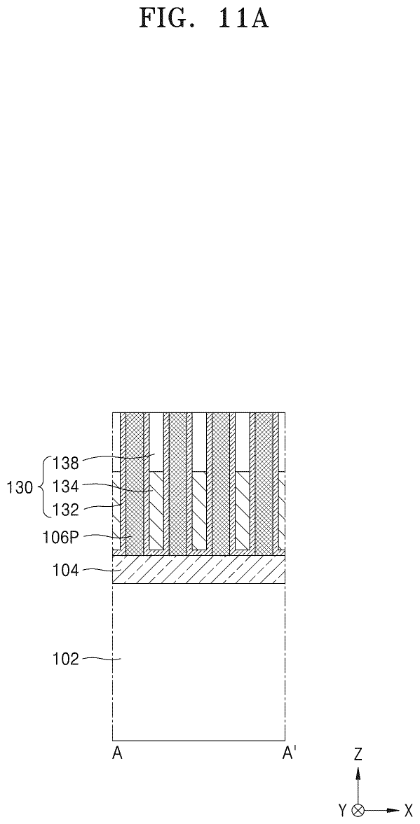

Referring to FIGS. 9A through 9D and 10A through 10D together, to remove portions on the upper sides of the preliminary separation insulating layer 136P and the preliminary word line layer 134P, a plurality of separation insulating layers 136 may be formed. For example, by removing portions on the upper sides of the preliminary separation insulating layer 136P and the preliminary word line layer 134P so that the upper surface of the plurality of word lines 134 and the upper surface of the plurality of back gate lines 116 are substantially at the same vertical level, the plurality of separation insulating layers 136 and the plurality of word lines 134 may be formed. The upper surface of the plurality of back gate lines 116 and the upper surface of the plurality of word lines 134 may be at a lower vertical level than the upper surface of the plurality of channel patterns 106P.

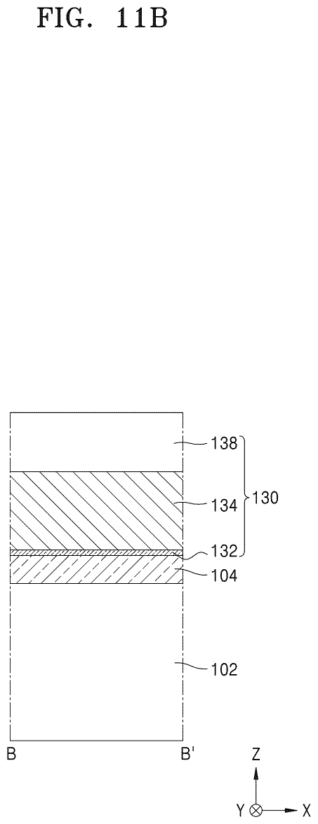

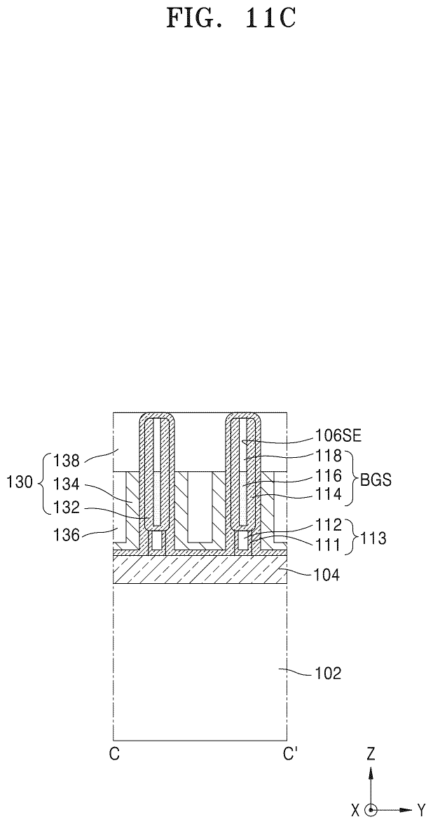

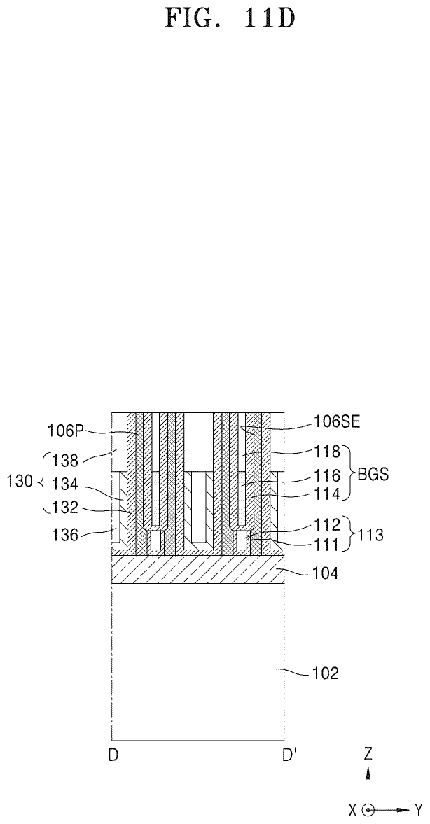

Referring to FIGS. 10A through 10D and 11A through 11D together, after forming a preliminary gate capping layer filling (A) spaces between the plurality of channel patterns 106P, which cover the preliminary gate insulating layer 132P, the plurality of separation insulating layers 136, and the plurality of word lines 134, and are adjacent to each other in the first horizontal direction (X direction), and (B) spaces between the plurality of back gate structures BGS in the second horizontal direction (Y direction), the plurality of gate capping layers 138 may be formed by removing a portion on the upper side of the preliminary gate capping layer. For example, the plurality of gate capping layers 138 may include silicon nitride. In the process of forming the plurality of gate capping layers 138, a portion of the upper side of the preliminary gate insulating layer 132P may also be removed, and the plurality of gate insulating layers 132 may be formed. The plurality of gate insulating layers 132, the plurality of word lines 134, and the plurality of gate capping layers 138 may constitute a plurality of word line structures 130. In the process of forming the plurality of gate capping layers 138, a portion of the lower mask pattern 107 and a portion of the plurality of insulating spacers 119, which remains on the plurality of channel patterns 106P, may all be removed.

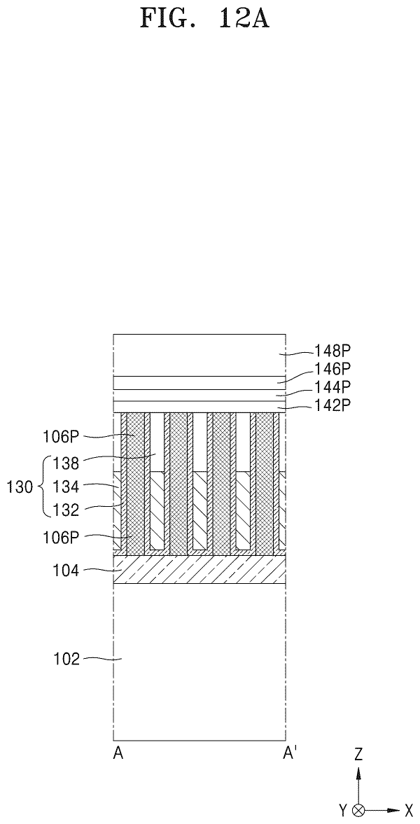

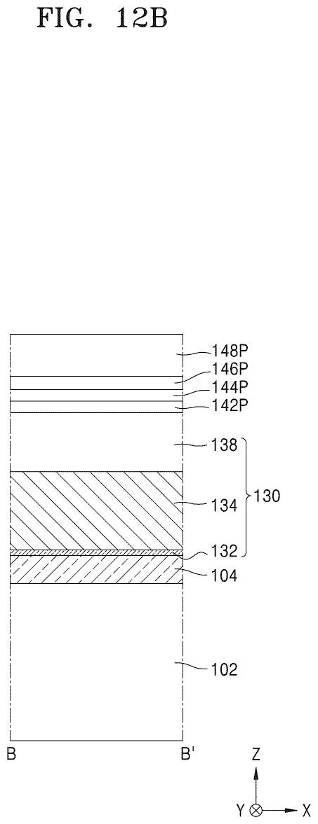

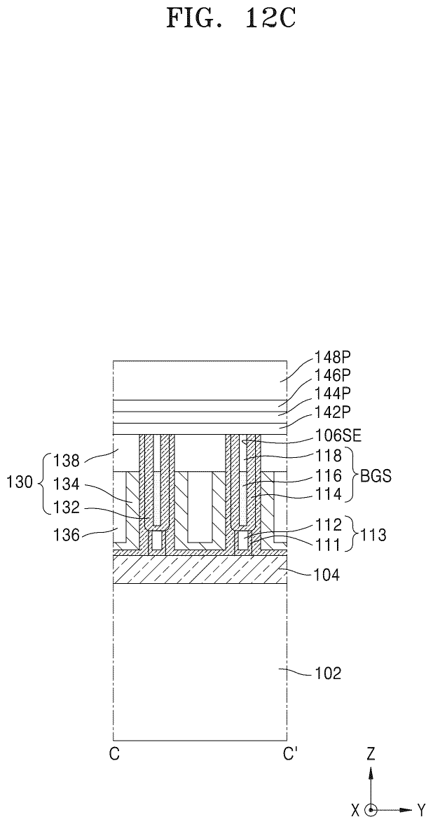

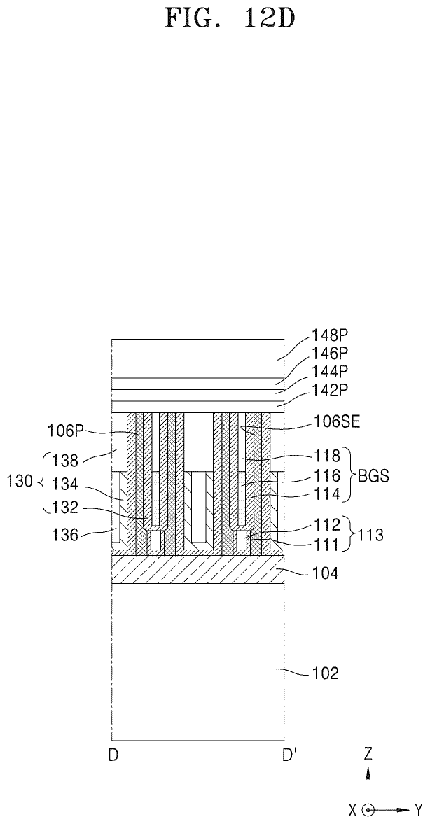

Referring to FIGS. 12A through 12D together, a first conductive material layer 142P, a second conductive material layer 144P, a third conductive material layer 146P, and a capping material layer 148P may be sequentially formed on the plurality of back gate structures BGS, the plurality of channel patterns 106P, and the plurality of word line structures 130.

The first conductive material layer 142P, the second conductive material layer 144P, and the third conductive material layer 146P may each include at least one of polysilicon, a metal, conductive metal nitride, conductive metal silicide, and conductive metal oxide. However, example embodiments are not limited thereto. Alternatively, at least one of the first conductive material layer 142P, the second conductive material layer 144P, and the third conductive material layer 146P may include a two-dimensional semiconductor material. In some example embodiments, the first conductive material layer 142P may include a semiconductor material, and the second conductive material layer 144P and the third conductive material layer 146P may each include a metal-based material. The second conductive material layer 144P and the third conductive material layer 146P may include metal-based materials of different types. For example, the first conductive material layer 142P may include doped polysilicon.

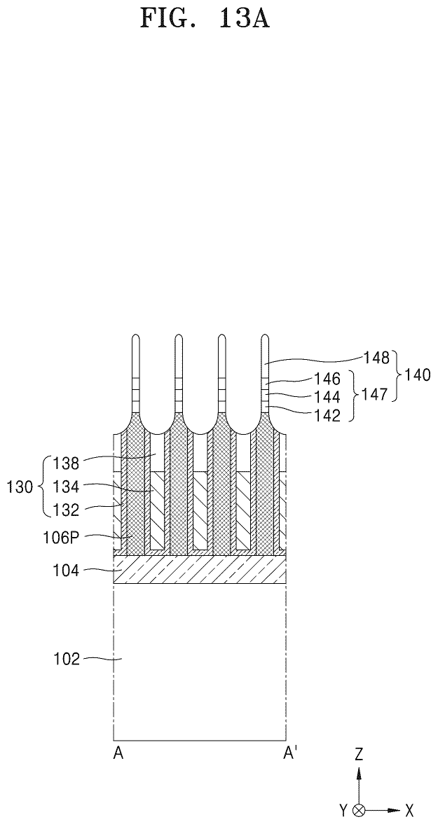

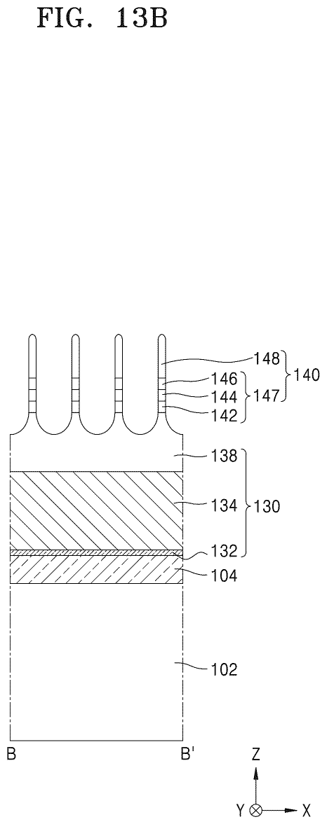

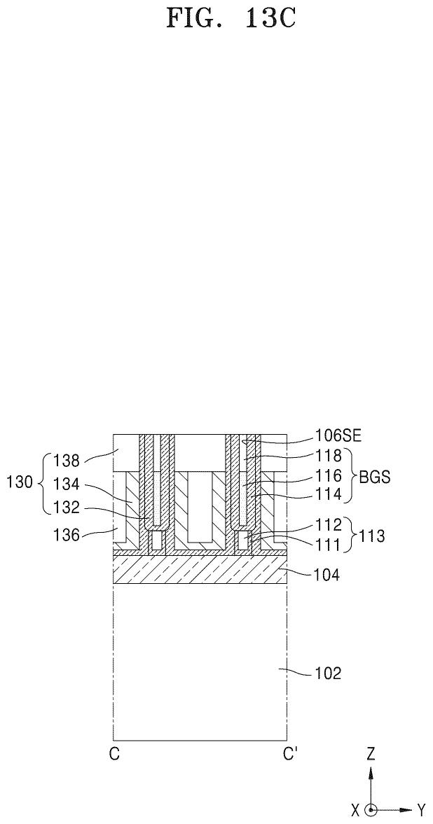

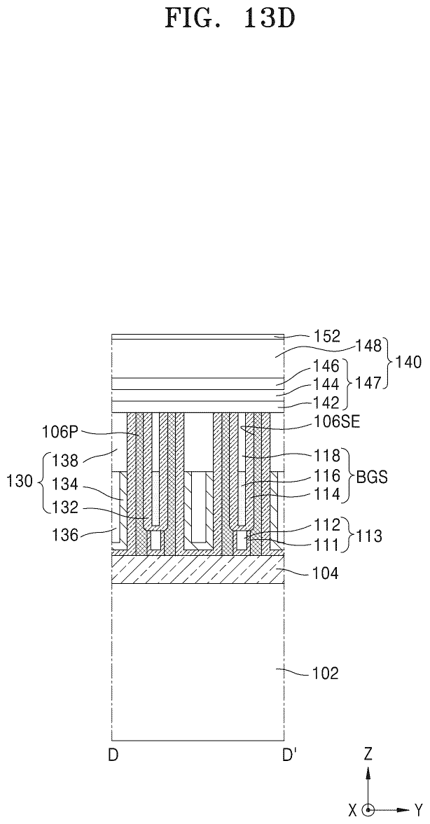

Referring to FIGS. 12A through 12D and 13A through 13D together, by patterning a stacked structure of the first conductive material layer 142P, the second conductive material layer 144P, and the third conductive material layer 146P, a plurality of bit line structures 140 may be formed. The plurality of bit line structures 140 may be apart from each other in the first horizontal direction (X direction) and may extend in parallel with each other in the second horizontal direction (Y direction). Each of the plurality of bit line structures 140 may include a bit line 147 and an insulating capping line 148 covering the bit line 147. The plurality of bit lines 147 and a plurality of insulating capping lines 148 may be apart from each other in the first horizontal direction (X direction) and may extend in parallel with each other in the second horizontal direction (Y direction).

Each of the plurality of bit lines 147 may include doped polysilicon, a metal, conductive metal nitride, conductive metal silicide, conductive metal oxide, or a combination thereof. However, example embodiments are not limited thereto. For example, the bit line 147 may include doped polysilicon, Al, Cu, Ti, Ta, Ru, W, Mo, Pt, Ni, Co, TiN, TaN, WN, WSi, NbN, TiAl, TiAlN, TiSi, TiSiN, TaSi, TaSiN, RuTiN, NiSi, CoSi, IrOₓ, RuOₓ, or a combination thereof, but example embodiments are not limited thereto. Alternatively, the bit line 147 may include a two- dimensional semiconductor material. The two-dimensional semiconductor material may include, for example, graphene, carbon nanotube, or a combination thereof. However, example embodiments are not limited thereto. The bit line 147 may have a single layer or a multilayer including the conductive materials described above. For example, each of the plurality of insulating capping lines 148 may include silicon nitride.

Each of the plurality of bit lines 147 may have a stacked structure of a first line pattern 142, a second line pattern 144, a third line pattern 146. For example, the first line pattern 142 may include a semiconductor material, and each of the second line pattern 144 and the third line pattern 146 may include a metal-based material. The second line pattern 144 and the third line pattern 146 may include metal-based materials different types. For example, the first line pattern 142 may include doped polysilicon. For example, the second line pattern 144 may include titanium nitride (TIN) or Ti-Si-N (TSN), and the third line pattern 146 may include tungsten (W), or tungsten and tungsten silicide (WSix). However, example embodiments are not limited thereto. In some example embodiments, the second line pattern 144 may perform a function of a diffusion barrier. The first line pattern 142, the second line pattern 144, the third line pattern 146, and the insulating capping line 148 may be portions of the first conductive material layer 142P, the second conductive material layer 144P, the third conductive material layer 146P, and the capping material layer 148P, respectively.

In some example embodiments, an interface insulating layer 152 may be arranged on some of the plurality of insulating capping lines 148. The interface insulating layer 152 may include silicon nitride.

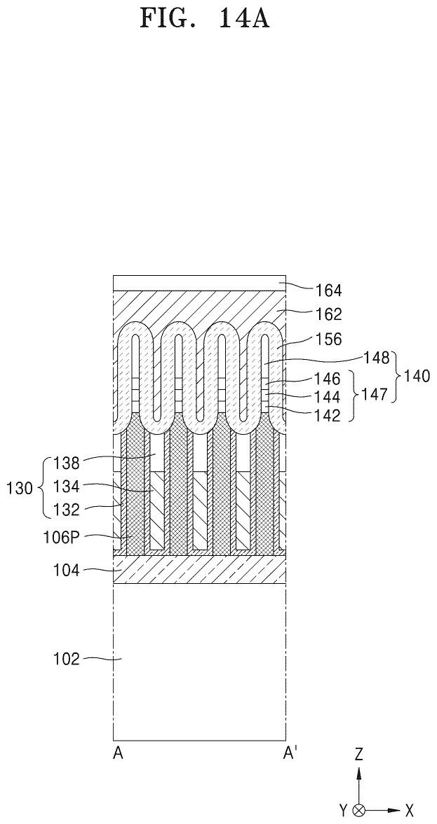

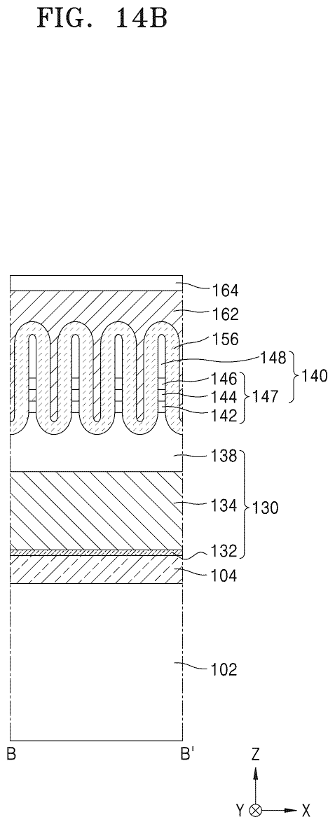

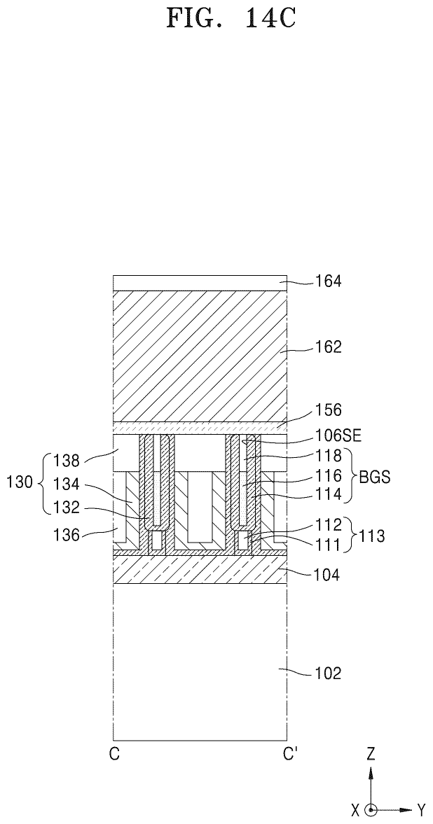

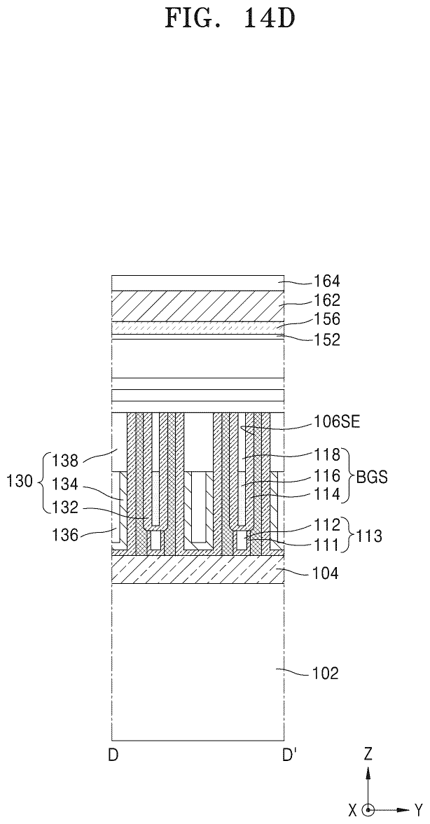

Referring to FIGS. 14A through 14D together, a cover insulating layer 156 filling a portion of each of the spaces between the plurality of bit line structures 140 may be formed. The cover insulating layer 156 may be formed to conformally cover the plurality of bit line structures 140 but may not completely fill the spaces between the plurality of bit line structures 140. The cover insulating layer 156 may include silicon oxide. Thereafter, a shield conductive layer 162, which covers the cover insulating layer 156 and fills spaces between the plurality of bit line structures 140, and a protection insulating layer 164 covering the shield conductive layer 162 may be sequentially formed. The shield conductive layer 162 may prevent interference from occurring between the plurality of bit lines 147. For example, the shield conductive layer 162 may include a metal material. For example, the protection insulating layer 164 may include silicon nitride.

Referring to FIGS. 14A through 14D and 15A together, before the cover insulating layer 156 is formed, a first charging insulating layer 154 may be formed in the dummy region MCD, where the plurality of bit line structures 140 have not been formed. The first charging insulating layer 154 may be formed to cover the gate capping layer 138 in the dummy region MCD. In some example embodiments, before forming the first charging insulating layer 154, the interface insulating layer 152 covering a portion of the gate capping layer 138 and a portion of the insulating capping line 148 may be formed. The interface insulating layer 152 may be formed to cover a portion of the dummy region MCD, in which the gate capping layer 138 is not formed. For example, the first charging insulating layer 154 may be formed on the interface insulating layer 152 in the dummy region MCD. For example, the first charging insulating layer 154 may include silicon oxide.

Thereafter, after the cover insulating layer 156 is formed, a shield material layer 162P, which covers the cover insulating layer 156 and fills spaces between the plurality of bit line structures 140, and a protection material layer 164P may be formed. The shield material layer 162P may be formed to cover both the memory cell array region MCA and the dummy region MCD.

Referring to FIGS. 14A through 14D, 15A, and 15B together, by removing a portion of the shield material layer 162P and a portion of the protection material layer 164P, the shield conductive layer 162 and the protection insulating layer 164 may be formed, respectively. The shield conductive layer 162 may be formed by removing a portion of the shield material layer 162P formed in the dummy region MCD. The shield conductive layer 162 may include a main body unit SLM arranged in the memory cell array region MCA, and a pad unit SLP extending from the main body unit SLM and arranged in the dummy region MCD. The main body unit SLM and the pad unit SLP may form one body. As illustrated in FIGS. 1A and 1B, the main body unit SLM may have a rectangular shape corresponding to the memory cell array region MCA in a plan view. In a plan view, the pad unit SLP may extend from a corner portion of the main body unit SLM. In some example embodiments, the shield conductive layer 162 may include four pad units SLP corresponding to one shield conductive layer SL. For example, the shield conductive layer 162 may, in a plan view, include four pad units SLP extending from four corner portions of the main body unit SLM.

To form the shield conductive layer 162 and the protection insulating layer 164, a second charging insulating layer 166 may fill a portion, where a portion of the shield material layer 162P and a portion of the protection material layer 164P are removed. For example, the second charging insulating layer 166 may include silicon oxide.

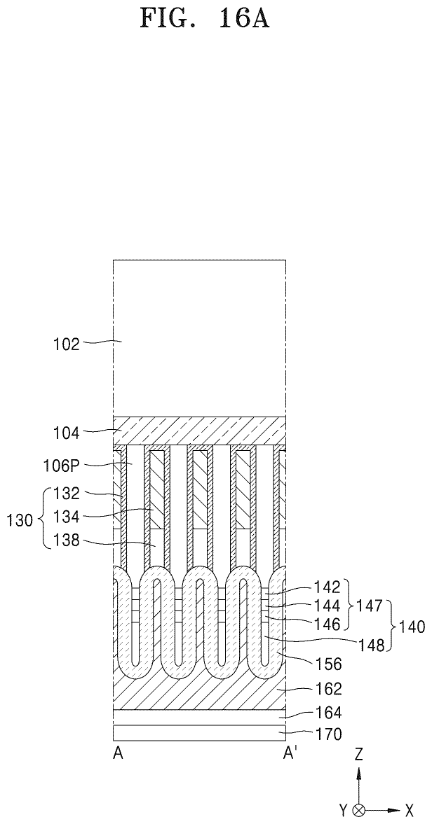

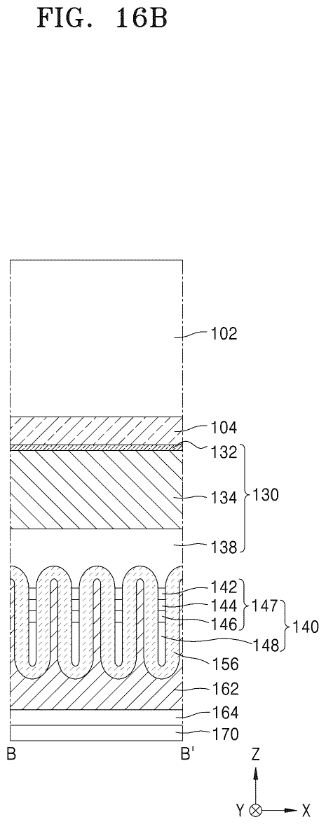

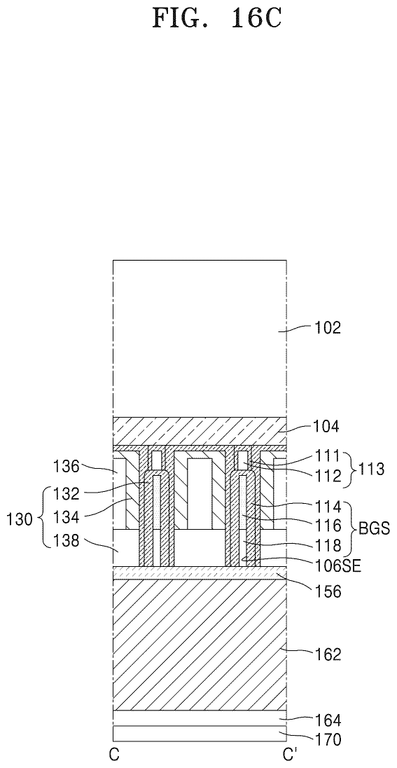

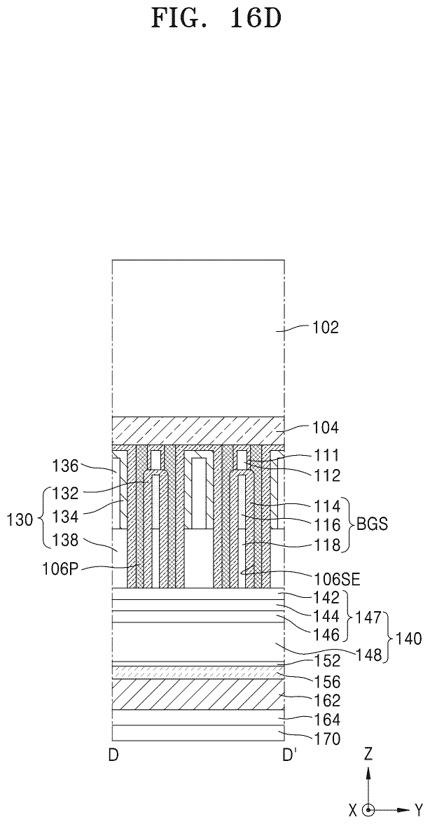

Referring to FIGS. 14A through 14D and 16A through 16D together, after a first bonding insulating layer 170 covering the protection insulating layer 164 is formed, the resultant product of FIGS. 14A through 14D may be flipped upside down so that the base substrate 102 is on the upper side of the resultant product and the first bonding insulating layer 170 is on the lower side of the resultant product. For example, the first bonding insulating layer 170 may include silicon oxide or silicon carbon nitride (SiCN). However, example embodiments are not limited thereto.

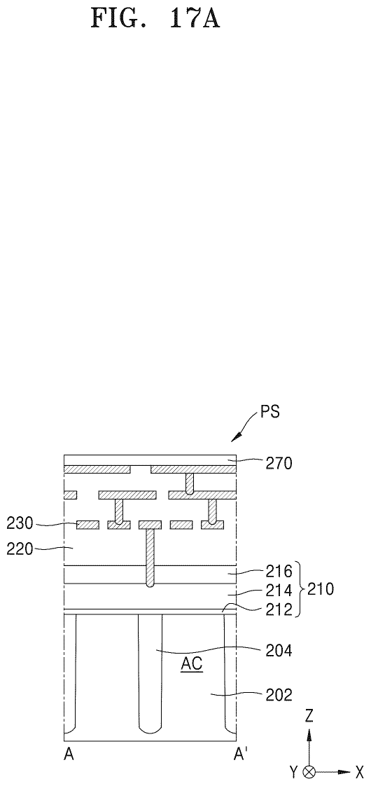

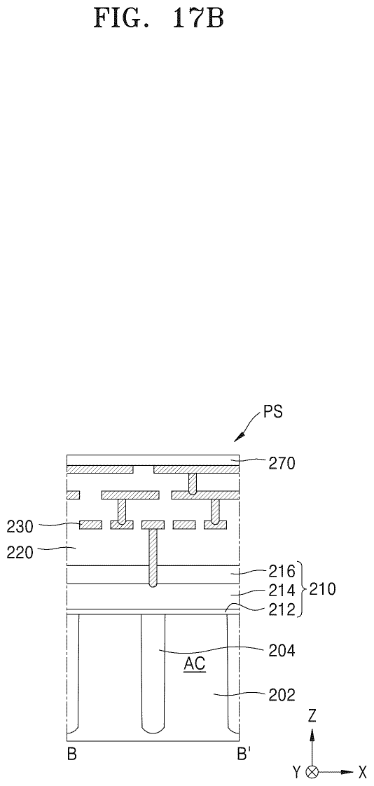

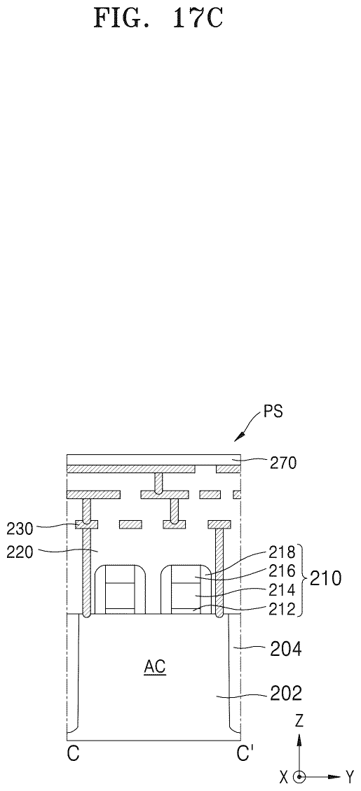

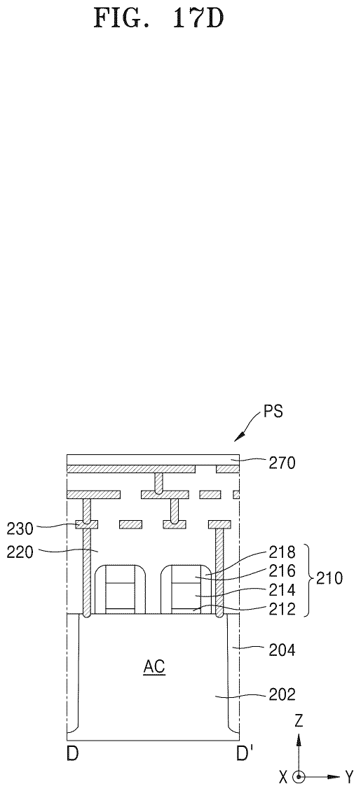

Referring to FIGS. 17A through 17D together, the periphery circuit structure PS may be prepared. The periphery circuit structure PS may include a circuit substrate 202 including an active region AC defined by a circuit element separation layer 204, a circuit gate structure 210 arranged in the active region AC of the circuit substrate 202, an inter-wiring insulating layer 220 covering the circuit gate structure 210 on the circuit substrate 202, a wiring structure 230 surrounded by the inter-wiring insulating layer 220 and electrically connected to the active region AC and/or the circuit gate structure 210, and a second bonding insulating layer 270 arranged on the inter-wiring insulating layer 220 and the wiring structure 230.

The circuit substrate 202 may include a semiconductor material, for example, a Group IV semiconductor material, a Group III-V semiconductor material, Group II-VI semiconductor material, or a Group II-VI oxide semiconductor material. The Group IV semiconductor material may include, for example, Si, Ge, or SiGe. The Group III-V semiconductor material may include, for example, GaAs, InP, GaP, InAs, indium antimony InSb, or InGaAs. The Group II-VI semiconductor material may include, for example, zinc telluride (ZnTe), or cadmium sulfide (CdS). However, example embodiments are not limited thereto. The circuit substrate 202 may include a bulk wafer or an epitaxial layer. The circuit substrate 202 may also be provided as a bulk wafer or an epitaxial layer. In other example embodiments, the circuit substrate 202 may include an SOI substrate or a GeOI substrate. The active region AC may be defined in the circuit substrate 202 by the circuit element separation layer 204, and the active region AC and the circuit gate structure 210 may constitute a plurality of periphery circuits.

The circuit gate structure 210 may include a circuit gate electrode 214 on the active region AC, a circuit gate insulating layer 212 arranged between the active region AC and the circuit gate electrode 214, a circuit gate capping layer 216 covering the circuit gate electrode 214, and a circuit gate spacer 218 covering side surfaces of the circuit gate insulating layer 212, the circuit gate electrode 214, and the circuit gate capping layer 216.

The wiring structure 230 may include a circuit wiring line and a circuit wiring contact. The wiring structure 230 may include a conductive material, for example, Cu, Al, W, Ag, Au, or a combination thereof. However, example embodiments are not limited thereto. The inter-wiring insulating layer 220 may include an insulating material, for example, silicon oxide, silicon nitride, a low-k material, or a combination thereof. However, example embodiments are not limited thereto. The low-k material may be a material having a lower dielectric constant than silicon oxide, and may include, for example, phosphosilicate glass (PSG), borophosphosilicate glass (BPSG), fluorosilicate glass (FSG), organosilicate glass (OSG), spin-on-glass (SOG), spin-on-polymer, or a combination thereof. However, example embodiments are not limited thereto. In some example embodiments, the inter-wiring insulating layer 220 may include an ultra-low k (ULK) layer having an ultra-low dielectric constant K of about 2.2 to about 2.4. The ULK layer may include a SiOC layer or a SiCOH layer.

The second bonding insulating layer 270 may include silicon oxide or SICN.

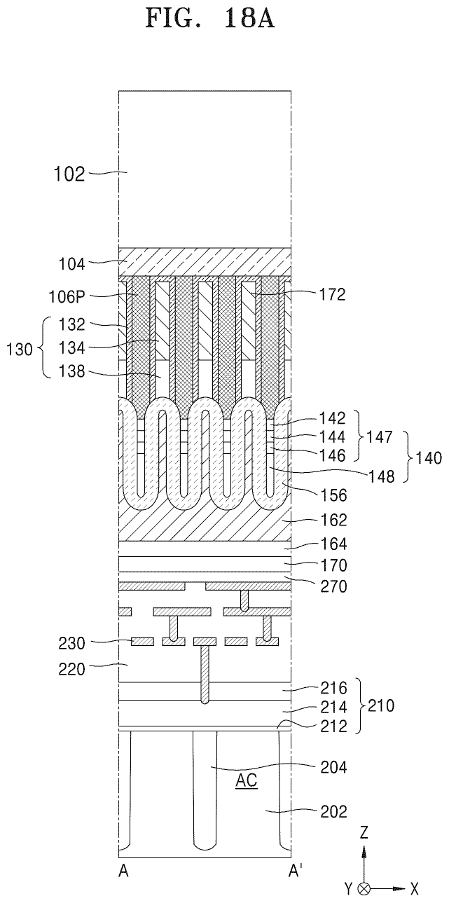

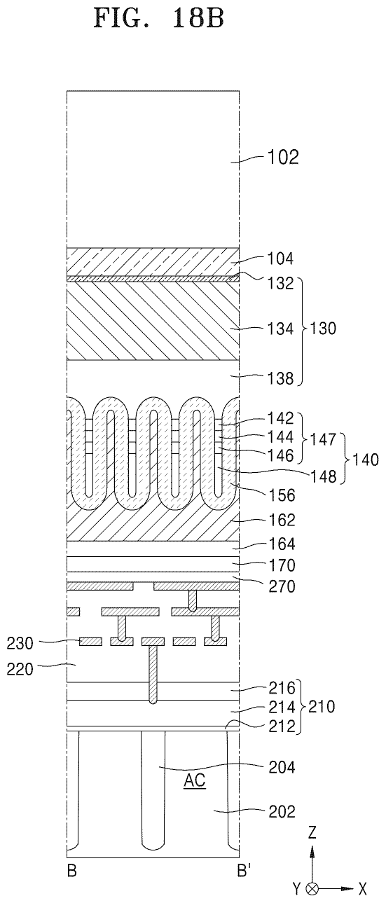

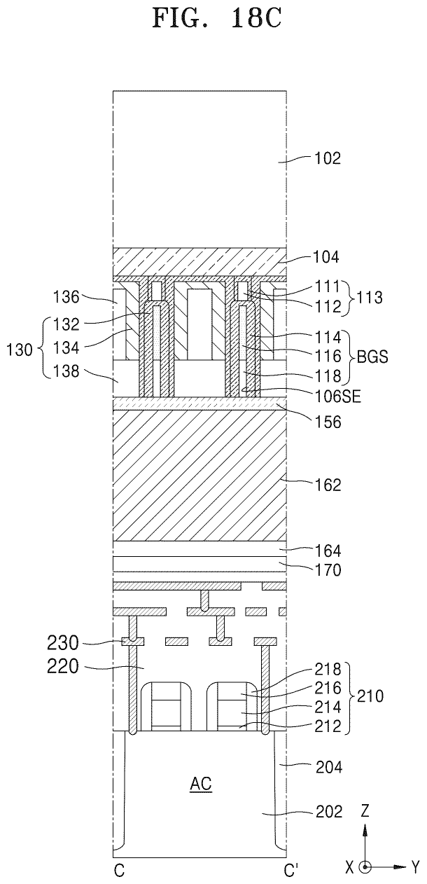

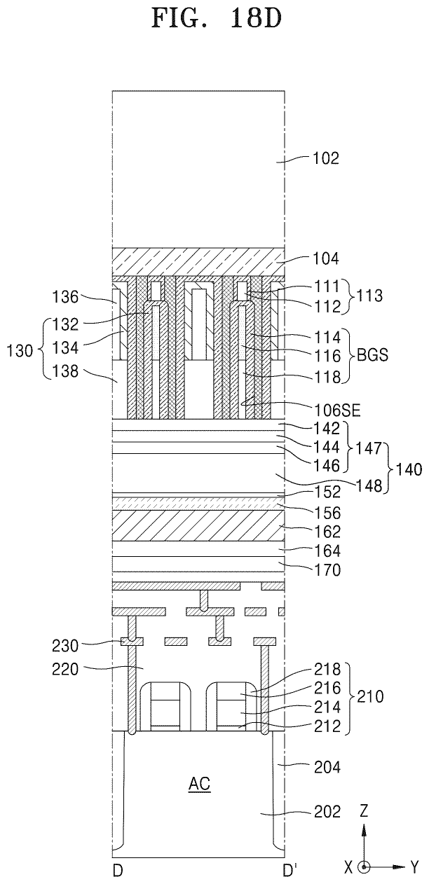

Referring to FIGS. 18A through 18D together, the resultant product of FIGS. 16A through 16D may be bonded to the periphery circuit structure PS illustrated in FIGS. 17A through 17D. The periphery circuit structure PS and the resultant product of FIGS. 16A through 16D may be bonded to each other by using a hybrid bonding method. For example, the second bonding insulating layer 270 and the first bonding insulating layer 170 may form a covalent bond and be bonded to each other.

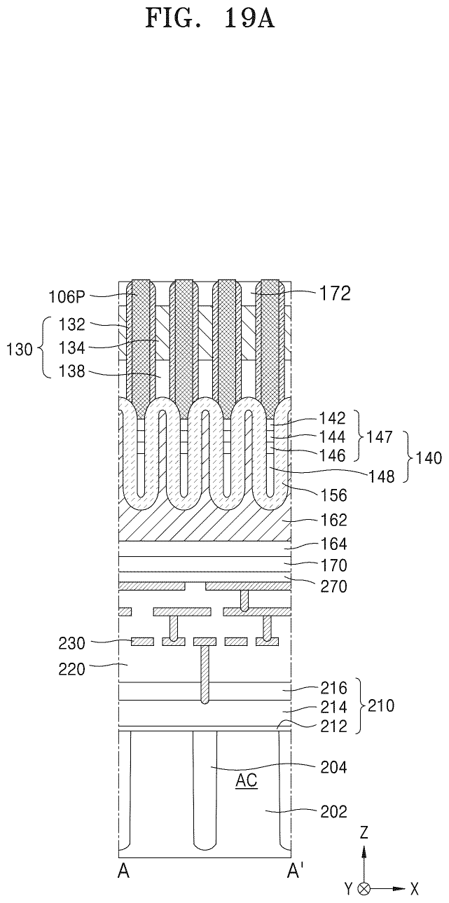

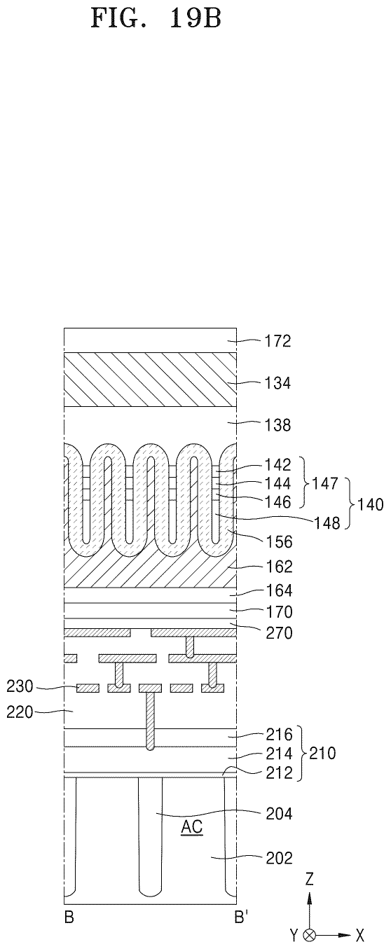

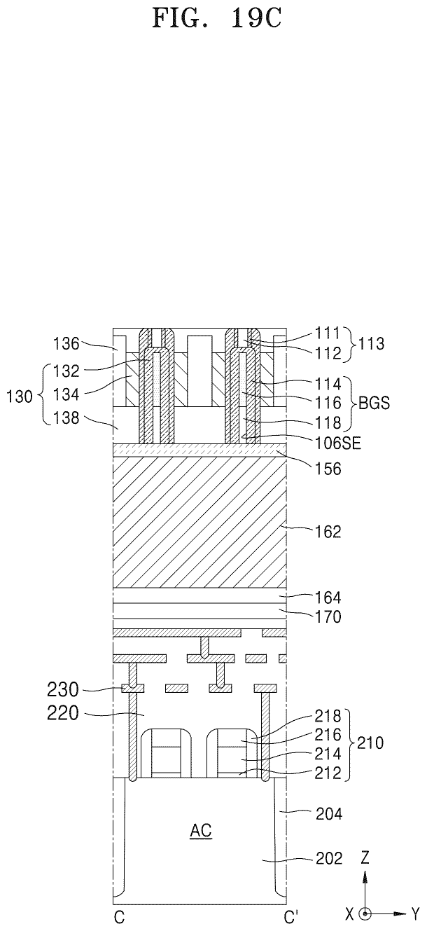

Referring to FIGS. 18A through 18D and 19A through 19D together, by removing the base substrate 102 and the base insulating layer 104, the plurality of channel patterns 106P and the plurality of word lines 134 may be exposed. In a process of removing the base substrate 102 and the base insulating layer 104, a portion of the plurality of gate insulating layers 132 may be removed together, and the plurality of word lines 134 may be exposed.

Thereafter, after a portion of the upper side of the plurality of word lines 134 is removed, a buried capping layer 172 filling space, where the portion of the upper side of the plurality of word lines 134 has been removed, may be formed. For example, the buried capping layer 172 may include silicon nitride.

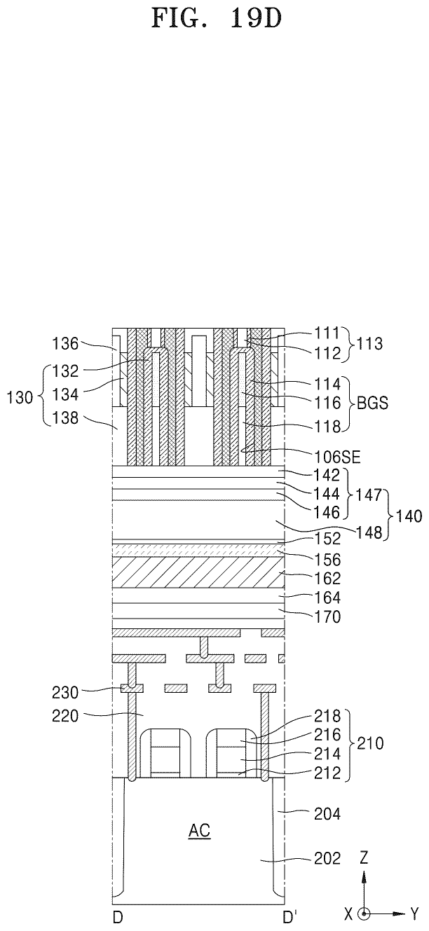

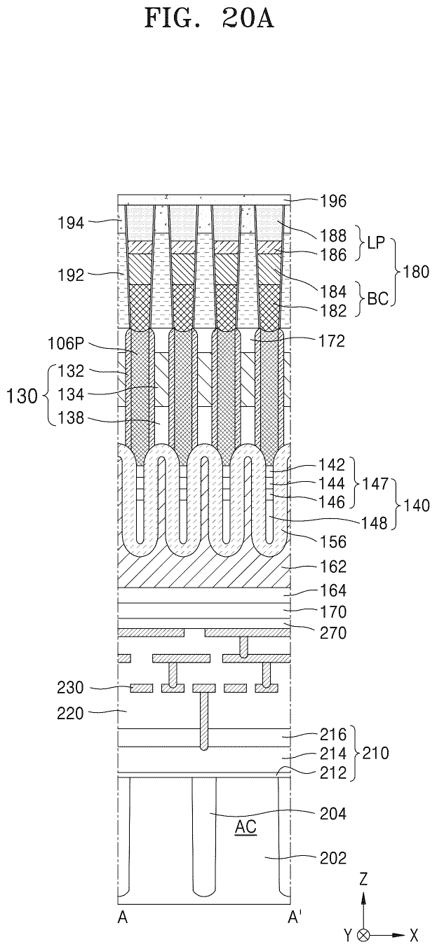

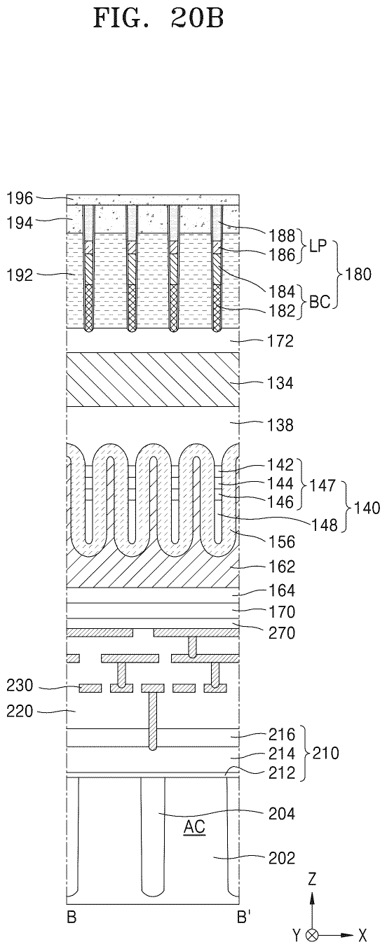

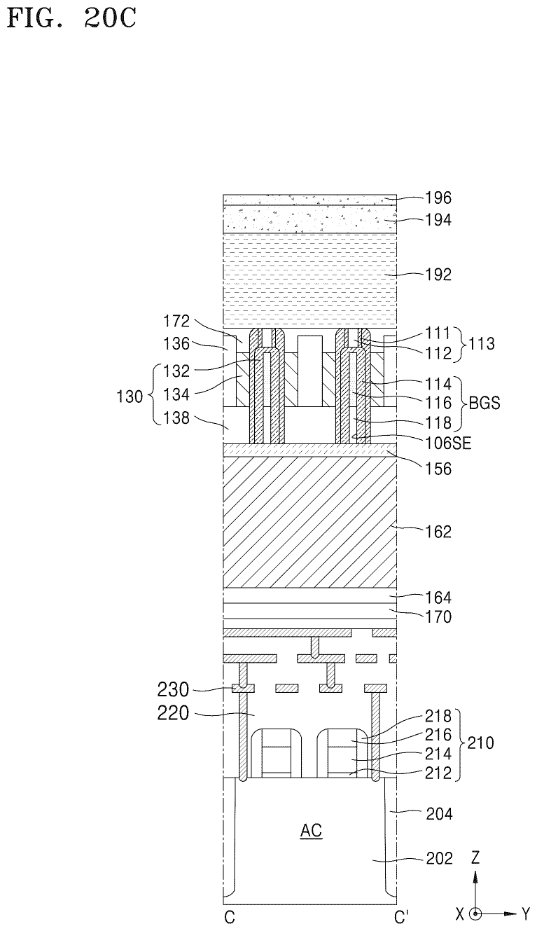

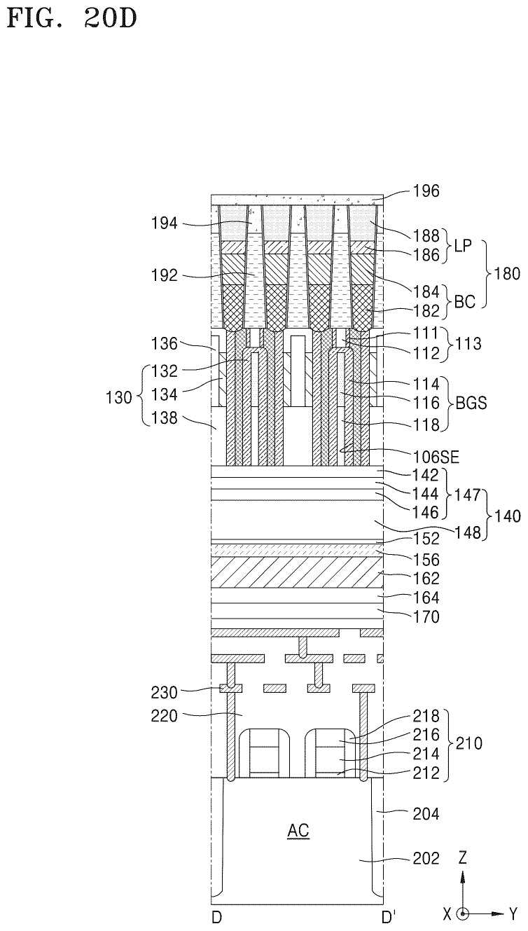

Referring to FIGS. 20A through 20D together, a plurality of connection structures 180 may be formed on the plurality of channel patterns 106P. The plurality of connection structures 180 may be surrounded by a first surrounding insulating layer 192 and a second surrounding insulating layer 194. Each of the plurality of connection structures 180 may include at least one of a conductive material, for example, a doped semiconductor material, a metal, conductive metal nitride, conductive metal carbide, metal silicide, conductive metal oxynitride, conductive metal oxide, and a two-dimensional (2D) material, but is not limited thereto.

Each of the plurality of connection structures 180 may include a lower connection structure BC and an upper connection structure LP. The lower connection structure BC and the upper connection structure LP corresponding to each other may be aligned with each other in the vertical direction (Z direction). The lower connection structure BC may have a stacked structure of a first semiconductor layer 182 and a second semiconductor layer 184. In some example embodiments, the first semiconductor layer 182 may include a single crystal semiconductor material, and the second semiconductor layer 184 may include a polycrystalline semiconductor material. For example, the first semiconductor layer 182 may be formed by using an epitaxial growth method using the channel pattern 106P as a seed. For example, the first semiconductor layer 182 may include single crystal silicon, and the second semiconductor layer 184 may include polysilicon. In some example embodiments, the upper connection structure LP may have a stacked structure of a silicide layer 186 and a metal plug 188. For example, the silicide layer 186 may include WSiₓ, NiSiₓ, CoSiₓ, or NiPtSiₓ, and the metal plug 188 may include W, Mo, Au, Cu, Al, Ni, or Co. However, example embodiments are not limited thereto. For example, the first surrounding insulating layer 192 may include silicon oxide, and the second surrounding insulating layer 194 may include silicon nitride.

An etching stop layer 196 may be formed on the plurality of connection structures 180 and the second surrounding insulating layer 194. For example, the etching stop layer 196 may include silicon nitride.

Referring to FIGS. 21A through 21D together, by forming a plurality of capacitor structures 300, which penetrate the etching stop layer 196 and are respectively and electrically connected to the plurality of connection structures 180, the semiconductor memory device 1 may be formed. The plurality of capacitor structures 300 may be formed by sequentially stacking a plurality of lower electrodes 310, a capacitor dielectric layer 320, and an upper electrode 330.

Each of the plurality of lower electrodes 310 may be electrically connected to each of the plurality of connection structures 180. Each of the plurality of connection structures 180 may include a lower connection structure BC and an upper connection structure LP. The lower connection structure BC may be arranged toward the channel pattern 106P and electrically connected to the channel pattern 106P, and the upper connection structure LP may be arranged toward the lower electrode 310 and electrically connected to the lower electrode 310.

Each of the plurality of lower electrodes 310 may have a column shape, that is, a pillar shape, with the filled inside to have a circular horizontal cross-section, but example embodiments are not limited thereto. In some example embodiments, each of the plurality of lower electrodes 310 may have a cylinder shape having a closed lower portion thereof. In some example embodiments, the plurality of lower electrodes 310 may be in a honeycomb zigzag shape with respect to the first horizontal direction (X direction) or the second horizontal direction (Y direction). In other example embodiments, the plurality of lower electrodes 310 may be in a line matrix in the first horizontal direction (X direction) and the second horizontal direction (Y direction), respectively. The plurality of lower electrodes 310 may include, for example, at least one of silicon doped with impurities, a metal such as tungsten and copper, or a conductive metal compound such as titanium nitride. However, example embodiments are not limited thereto.

The capacitor dielectric layer 320 may conformally cover surfaces of the plurality of lower electrodes 310. In some example embodiments, the capacitor dielectric layer 320 may be formed to cover the plurality of lower electrodes 310 together in one body within a certain region. The capacitor diclectric layer 320 may include, for example, TaO, TaAIO, TaON, AlO, AISIO, HfO, HfSiO, ZrO, ZrSiO, TiO, TiAlO, (Ba, Sr)TiO (BST), SrTIO (STO), BaTiO (BTO), Pb(Zr, Ti)O (PZT), (Pb,La)(Zr,Ti)O, Ba(Zr,Ti)O, Sr(Zr,Ti)O, or a combination thereof. However, example embodiments are not limited thereto.

The upper clectrode 330 may include, for example, W, Ru, RuO, Pt, PtO, Ir, IrO, SRO(SrRuO), BSRO((Ba,Sr)RuO), CRO(CaRuO), BaRuO, La(Sr,Co)O, etc. However, example embodiments are not limited thereto. In some example embodiments, the upper electrode 330 may include a metal material. For example, the upper electrode 330 may include W. In some example embodiments, the upper electrode 330 may further include at least one of a doped semiconductor material layer and an interface layer, in addition to a metal material, and may have a stacked structure of these materials. The doped semiconductor material may include at least one of, for example, doped polysilicon and doped polycrystalline silicon germanium (SiGe). The interface layer may include at least one of, for example, metal oxide, metal nitride, metal carbide, and metal silicide.

Referring to FIGS. 1A through 1C and 21A through 21D together, the semiconductor memory device 1 may include the plurality of bit line structures 140 on the periphery circuit structure PS, the plurality of back gate structures BGS respectively on the plurality of bit line structures 140, a transistor structure including the plurality of word line structures 130 and the plurality of channel patterns 106P, the plurality of capacitor structures 300 on the transistor structure, and the plurality of connection structures 180 respectively and electrically connecting the plurality of channel patterns 106P respectively to the plurality of capacitor structures 300. The plurality of channel patterns 106P may be electrically connected to the plurality of lower electrodes 310 via the plurality of connection structures 180, respectively. The plurality of word line structures 130 and the plurality of channel patterns 106P included in the transistor structure may constitute a plurality of transistors. Each of the plurality of transistors may include a vertical channel transistor (VCT).

Each of the plurality of back gate structures BGS may include the back gate insulating layer 114, the back gate line 116, and the back gate capping layer 118. Each of the plurality of word line structures 130 may include the gate insulating layer 132, the word line 134, and the gate capping layer 138. The back gate insulating layer 114, the back gate line 116, the gate insulating layer 132, and the word line 134 may correspond to the back gate insulating layer BGox, the back gate line BG, the gate insulating layer Gox, and the word line WL illustrated in FIGS. 1A through 1C, respectively.

The back gate line 116 and the plurality of word lines 134 may be apart from each other in the second horizontal direction (Y direction) and may extend in parallel with each other in the first horizontal direction (X direction). Each of the plurality of back gate lines 116 may be arranged between an adjacent pair of word lines 134 among the plurality of word lines 134. For example, two word lines 134 among the plurality of word lines 134 and one back gate line 116 may be arranged alternately in the second horizontal direction (Y direction).

The plurality of channel patterns 106P may be arranged in a row in the first horizontal direction (X direction), between one word line 134 and one back gate line 116, which are adjacent to each other, among the plurality of word lines 134 and the plurality of back gate lines 116. The plurality of channel patterns 106P may be arranged in a row in the second horizontal direction (Y direction). For example, each of the plurality of channel patterns 106P arranged in one row in the second horizontal direction (Y direction) may be arranged between one word line 134 and one back gate line 116 adjacent to each other in the second horizontal direction (Y direction). The channel pattern 106P may correspond to the channel pattern CH illustrated in FIG. IC.

Each of the plurality of bit line structures 140 may include a bit line 147 and an insulating capping line 148 below the bit line 147. The plurality of bit line structures 140 may be apart from each other in the first horizontal direction (X direction) and may extend in parallel with each other in the second horizontal direction (Y direction). The plurality of bit lines 147 and a plurality of insulating capping lines 148 may be apart from each other in the first horizontal direction (X direction) and may extend in parallel with each other in the second horizontal direction (Y direction). The plurality of bit lines 147 may be respectively and electrically connected to the plurality of channel patterns 106P.

The shield conductive layer 162 may be arranged below the plurality of bit lines 147 extending in the vertical direction respectively opposite to the plurality of channel patterns 106P. The cover insulating layer 156 may be arranged between the plurality of bit lines 147 and the shield conductive layer 162. The cover insulating layer 156 may be formed to conformally surround the plurality of bit line structures 140 including the plurality of bit lines 147 and may not completely fill spaces between the plurality of bit line structures 140. The shield conductive layer 162 may fill spaces between the plurality of bit line structures 140 including the plurality of bit lines 147 and may cover the plurality of bit lines 147 opposite to the plurality of channel patterns 106P. The bit line 147, the cover insulating layer 156, and shield conductive layer 162 may correspond to the bit line BL, the cover insulating layer BLO, and the shield conductive layer SL illustrated in FIGS. 1A through 1C.

The shield conductive layer SL may include the main body unit SLM arranged in the memory cell array region MCA and the pad unit SLP extending from the main body unit SLM and arranged in the dummy region MCD. The main body unit SLM and the pad unit SLP may form one body. The main body unit SLM may have a rectangular shape corresponding to the memory cell array region MCA in a plan view. In a plan view, the pad unit SLP may extend from a corner portion of the main body unit SLM. In some example embodiments, the shield conductive layer SL may include four pad units SLP corresponding to one shield conductive layer SL. For example, the shield conductive layer SL may, in a plan view, include four pad units SLP extending from four corner portions of the main body unit SLM.

The pad unit SLP may have a rectangular shape in a plan view. In a plan view, among four edges of the pad unit SLP, one edge extending in the first horizontal direction (X direction) of two edges opposite to the main body unit SLM may be aligned with one end of each of the plurality of bit lines BL in the first horizontal direction (X direction). In a plan view, among four edges of the pad unit SLP, the other one edge extending in the second horizontal direction (Y direction) of two edges opposite to the main body unit SLM may be aligned with one end of each of the plurality of word lines WL in the second horizontal direction (Y direction).

The semiconductor memory device 1 according to the inventive concepts may be formed so that the plurality of bit lines BL extending and protruding from the shield conductive layer 162 in a plan view, and a portion of each of the plurality of word lines WL do not further extend from the periphery of the pad unit SLP to the outside. Accordingly, the area occupied by the plurality of bit lines BL and the plurality of word lines WL decreases in the semiconductor memory device 1, and thus, the degree of integration of the semiconductor memory device 1 may be improved.

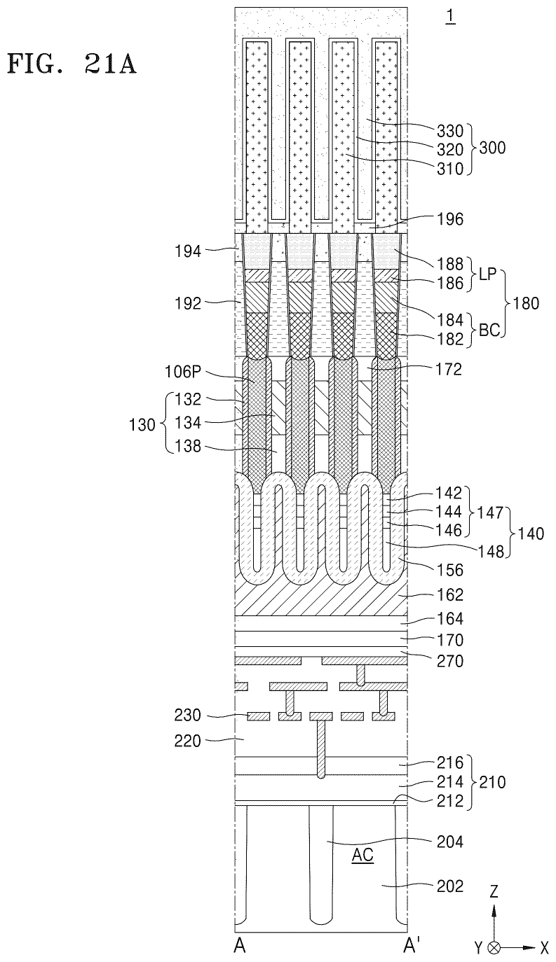

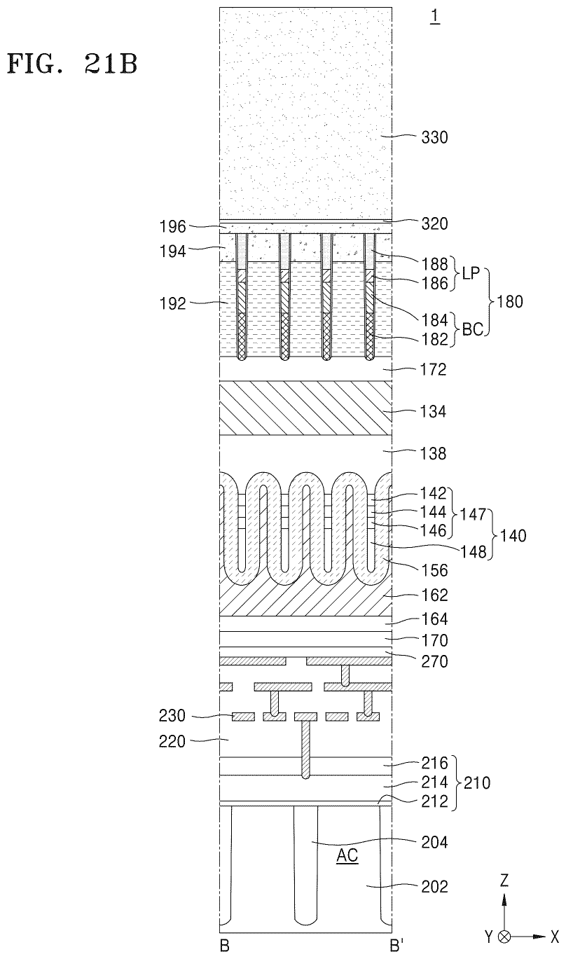

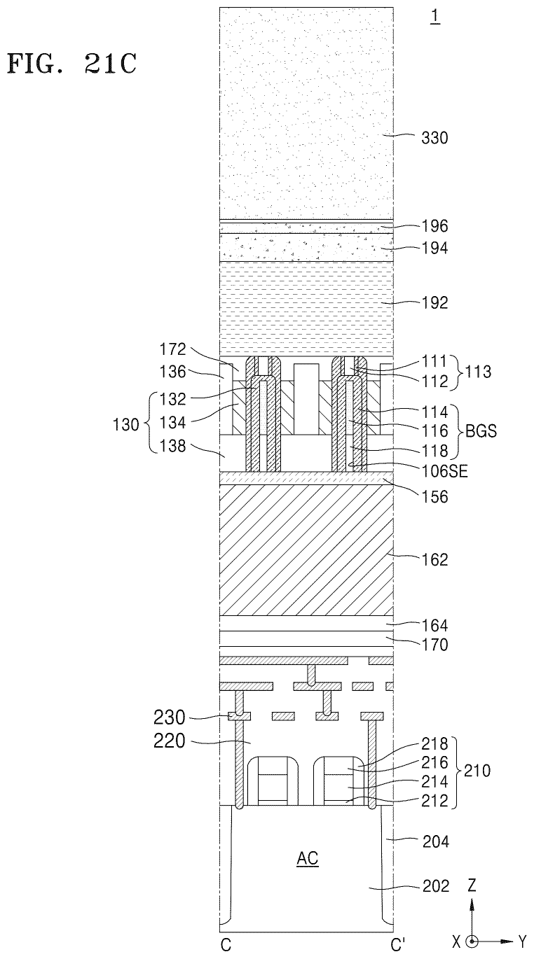

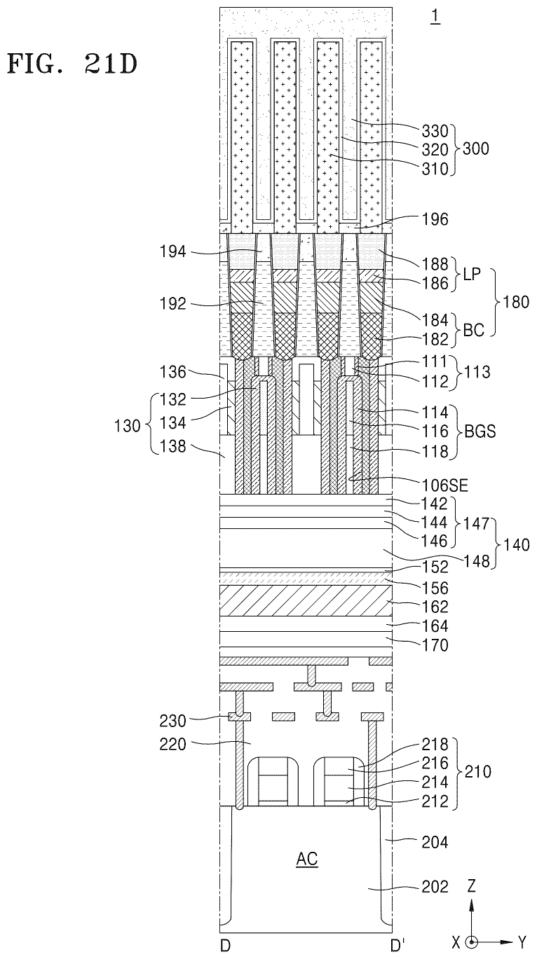

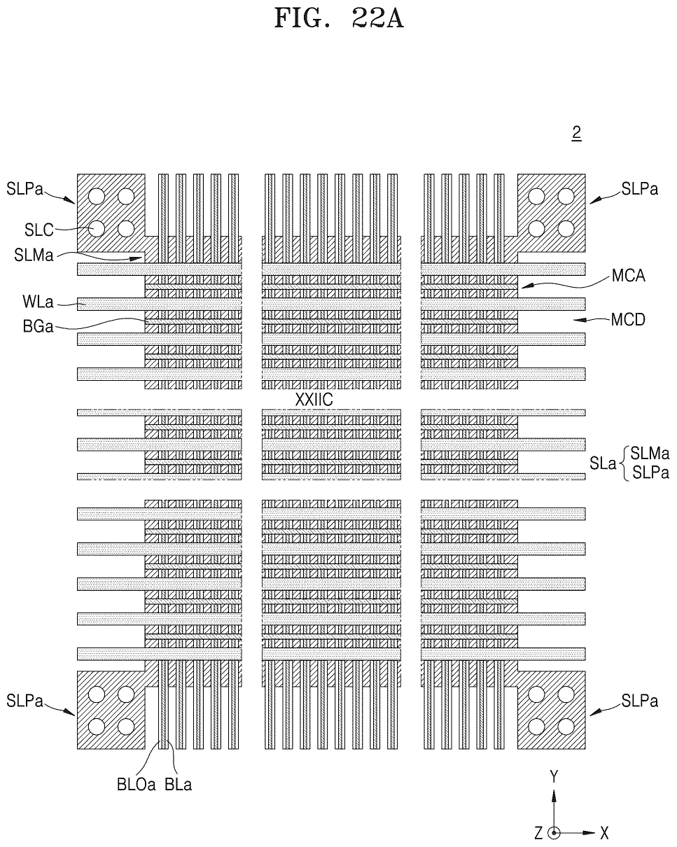

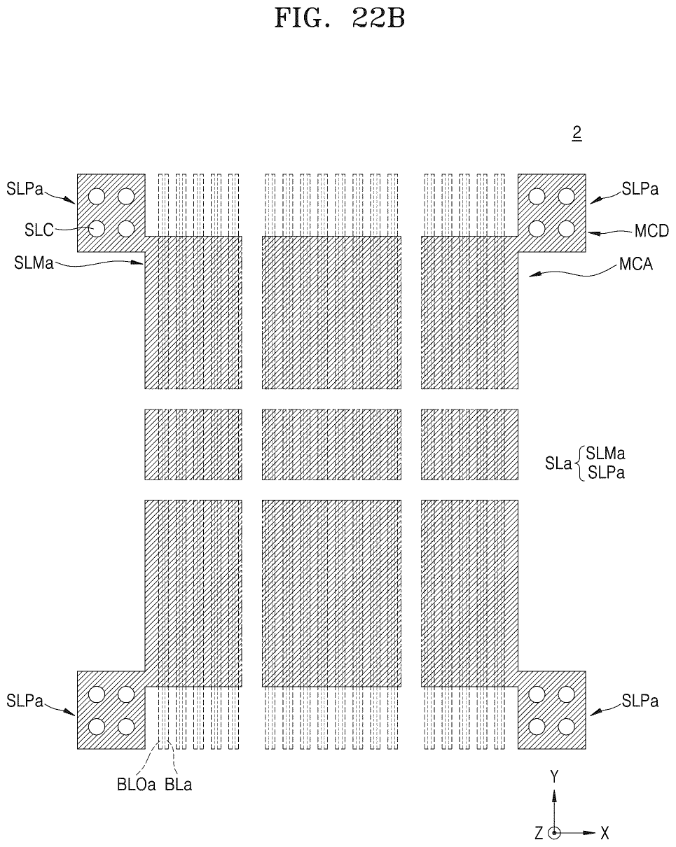

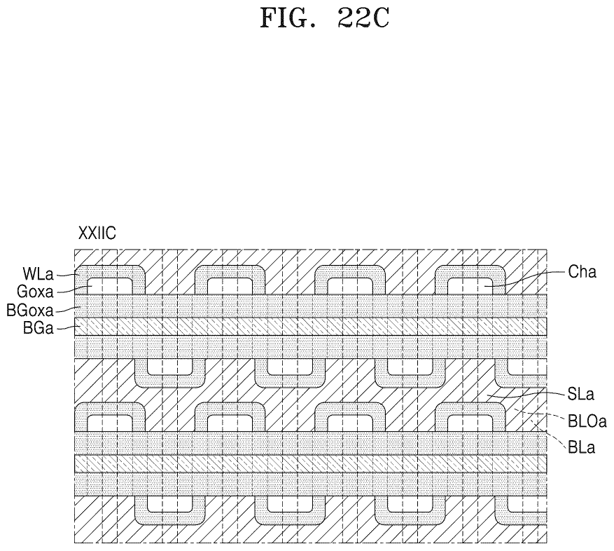

FIGS. 22A through 22C are plan layouts of a semiconductor memory device 2 according to example embodiments. FIG. 22A is a plan layout of some components of the semiconductor memory device 2, FIG. 22B is a plan layout of a shield conductive layer included in the semiconductor memory device 2, and FIG. 22 is a detailed plan layout of portion XXIIC in FIG. 22A. In FIGS. 22A through 22C, duplicate descriptions of given with reference to FIGS. 1A through 21D are omitted.

Referring to FIGS. 22A and 22B, the semiconductor memory device 2 may include the memory cell array region MCA and the dummy region MCD surrounding the memory cell array region MCA. The semiconductor memory device 2 may include a plurality of word lines WLa extending in a first horizontal direction (X direction), a plurality of bit lines BLa extending in a second horizontal direction (Y direction) different from the first horizontal direction (X direction), and a plurality of back gate lines BGa extending in the first horizontal direction (X direction).

The plurality of word lines WLa and the plurality of back gate lines BGa may be apart from each other in the second horizontal direction (Y direction) and may extend in parallel with each other in the first horizontal direction (X direction). For example, the plurality of word lines WLa and the plurality of back gate lines BGa may be arranged alternately in the second horizontal direction (Y direction).

The plurality of bit lines BLa may be apart from each other in the first horizontal direction (X direction) and may extend in parallel with each other in the second horizontal direction (Y direction). A cover insulating layer BLOa may cover the plurality of bit lines BLa. The cover insulating layer BLOa may be formed to conformally surround the plurality of bit lines BLa and may not completely fill spaces between the plurality of bit lines BLa. Shield conductive layers SLa may include the cover insulating layer BLOa therebetween and cover the plurality of bit lines BLa. Spaces between the plurality of bit lines BLa, that has not been completely filled by the cover insulating layer BLOa may be filled by the shield conductive layer SLa.

The plurality of word lines WLa may extend from the memory cell array region MCA to the dummy region MCD. The plurality of bit lines BLa may extend from the memory cell array region MCA to the dummy region MCD.

The shield conductive layer SLa may be overlapped with all of the memory cell array region MCA. For example, the shield conductive layer SLa may include a main body unit SLMa arranged in the memory cell array region MCA, and a pad unit SLPa extending from the main body unit SLMa and arranged in the dummy region MCD. The main body unit SLMa and the pad unit SLPa may form one body. The main body unit SLMa may have a rectangular shape corresponding to the memory cell array region MCA in a plan view. In a plan view, the pad unit SLPa may extend from a corner portion of the main body unit SLMa. In some example embodiments, the shield conductive layer SLa may include four pad units SLPa corresponding to one shield conductive layer SLa. For example, the shield conductive layer SLa may, in a plan view, include four pad units SLPa extending from four corner portions of the main body unit SLMa. The plurality of shield contacts SLC may be arranged in the pad unit SLPa.

The pad unit SLPa may have a rectangular shape in a plan view. In a plan view, among four edges of the pad unit SLPa, one edge extending in the first horizontal direction (X direction) of two edges opposite to the main body unit SLMa may be aligned with one end of each of the plurality of bit lines BLa in the first horizontal direction (X direction). In a plan view, among four edges of the pad unit SLPa, the other one edge extending in the second horizontal direction (Y direction) of two edges opposite to the main body unit SLMa may be aligned with one end of each of the plurality of word lines WLa in the second horizontal direction (Y direction).

Referring to FIGS. 22A through 22C together, the semiconductor memory device 2 may include the plurality of word lines WLa extending in the first horizontal direction (X direction), the plurality of bit lines BLa extending in the second horizontal direction (Y direction), the plurality of back gate lines BGa extending in the first horizontal direction (X direction), and a plurality of channel patterns CHa extending in the vertical direction (Z direction).

The plurality of channel patterns CHa may be arranged in a row in the first horizontal direction (X direction), between one word line WLa and one back gate line BGa, which are adjacent to each other, among the plurality of word lines WLa and the plurality of back gate lines BGa. The channel patterns CHa arranged between a pair of back gate lines BGa adjacent to each other among the plurality of back gate lines BGa may be arranged in a zigzag shape in the first horizontal direction (X direction). For example, between a pair of back gate lines BGa among the plurality of back gate lines BGa, the channel patterns CHa may be arranged in a pair of rows extending in the first horizontal direction (X direction), and the channel patterns CHa arranged in a pair of rows between the pair of back gate lines BGa may be alternately arranged in a pair of rows to form a zigzag shape in the first horizontal direction (X direction).

Each of the plurality of channel patterns CHa may include a first sidewall facing the back gate line BGa and a second sidewall facing the word line WLa and connected to an edge portion of the first sidewall. The first sidewall may have a plane and the second sidewall may have a curved surface. In other words, in a plan view, the first sidewall may have a linear shape, and the second sidewall may have a curved shape. For example, in a plan view, each of the plurality of channel patterns CHa may have a rectangular shape, in which two corners facing the word line WLa are rounded, or the second sidewall has an arc shape or an elliptical arc shape.

A gate insulating layer Goxa may be arranged between the channel pattern CHa and the word line WLa, and a back gate insulating layer BGoxa may be arranged between the channel pattern CHa and the back gate line BGa. In some example embodiments, the gate insulating layer Goxa may be formed to surround at least a portion of the channel pattern CHa in a plan view. In some example embodiments, the back gate insulating layer BGoxa may extend in the first horizontal direction (X direction) along each side of the back gate line BGa in the second horizontal direction (Y direction). The back gate insulating layer BGoxa may cover the first sidewall of the channel pattern CHa, and the gate insulating layer Goxa may cover the second sidewall.

The plurality of bit lines BLa may be apart from each other in the first horizontal direction (X direction) and may extend in parallel with each other in the second horizontal direction (Y direction). The plurality of bit lines BLa may extend in the second horizontal direction (Y direction) and may be electrically connected to the plurality of channel patterns CHa. For example, the plurality of bit lines BLa may be electrically connected to one end of the plurality of channel patterns CHa in the vertical direction (Z direction). One bit line BLa may be electrically connected to only one of channel patterns CHa arranged between a pair of back gate lines BGa adjacent to each other among the plurality of back gate lines BGa. Each of a pair of bit lines BLa adjacent to each other in the first horizontal direction (X direction) may be electrically connected to the channel pattern CHa arranged in a different row among the channel patterns CHa arranged in a pair of rows between a pair of back gate lines BGa.

The bit line BLa, the word line WLa, the channel pattern CHa adjacent to a portion of the word line WLa crossing the bit line BLa in a plan view, and the gate insulating layer Goxa arranged between the word line WLa and the channel pattern CHa may constitute a vertical channel transistor.

While the inventive concepts have been particularly shown and described with reference to example embodiments thereof, it will be understood that various changes in form and details may be made therein without departing from the spirit and scope of the following claims.

What is claimed is:

1. A semiconductor memory device comprising:
a plurality of word lines extending in a first horizontal direction;
a plurality of channel patterns adjacent to a plurality of word line structures, arranged in a row in the first horizontal direction, and extending in a vertical direction;
a plurality of bit lines extending in a second horizontal direction different from the first horizontal direction and electrically connected to a plurality of channel patterns;
the plurality of word lines adjacent to the plurality of channel patterns, and the plurality of channel patterns on the bit lines;
a shield conductive layer arranged below the plurality of bit lines and extending in the vertical direction between the bit lines; and
a cover insulating layer arranged between the plurality of bit lines and the shield conductive layer,
wherein in a plan view the shield conductive layer comprises a main body unit and a pad unit,
the plurality of bit lines overlapping the main body unit in the vertical direction, and
a pad unit extending from the main body unit but the plurality of bit lines not overlapping the pad unit in the vertical direction.

2. The semiconductor memory device of claim 1,
wherein the main body unit has a rectangular shape in a plan view, and
each of the pad units extend from a corner portion of the main body unit in a plan view.

3. The semiconductor memory device of claim 2,
wherein a number of pad units extending from four corner portions of the main body unit is four.

4. The semiconductor memory device of claim 2,
wherein the pad unit has a rectangular shape having a less area than the main body unit in a plan view.

5. The semiconductor memory device of claim 4,
wherein, in a plan view, an edge of the pad unit opposite to the main body unit and extending in the first horizontal direction among the four edges of the pad unit is aligned with one end of each of the plurality of bit lines in the first horizontal direction.

6. The semiconductor memory device of claim 4,
wherein, in a plan view, an edge of the pad unit opposite to the main body unit and extending in the second horizontal direction among the four edges of the pad unit is aligned with one end of each of the plurality of word lines in the second horizontal direction.

7. The semiconductor memory device of claim 4, wherein, in a plan view, one of two edges of the pad unit facing the main body unit is aligned with one of the four edges of the main body unit.

8. The semiconductor memory device of claim 4,
wherein, in a plan view, a distance between edges opposite to each other of two pad units among the four pad units aligned with each other in the second horizontal direction is identical to an extension length of the plurality of bit lines in the second horizontal direction.

9. The semiconductor memory device of claim 4,
wherein, in a plan view, a distance between edges opposite to each other of two pad units among the four pad units aligned with each other in the first horizontal direction is identical to an extension length of the plurality of word lines in the first horizontal direction.

10. The semiconductor memory device of claim 1,
wherein the cover insulating layer conformally surrounds the plurality of bit lines so that spaces between the plurality of bit lines are not completely filled, and
wherein the shield conductive layer fills spaces between the plurality of bit lines, which have not been completely filled by the cover insulating layer.

11. A semiconductor memory device comprising:
a plurality of word lines extending in a first horizontal direction;
a plurality of back gate lines extending in the first horizontal direction, and arranged apart from the plurality of word lines in a second horizontal direction different from the first horizontal direction;
a plurality of channel patterns arranged between the word line and the back gate line adjacent to each other among the plurality of word lines and the plurality of back gate lines, and extending in a vertical direction;
a plurality of bit lines extending in the second horizontal direction and electrically connected to the plurality of channel patterns;
the plurality of bit lines are arranged below the plurality of word lines, and adjacent to the plurality of back gate lines, and the plurality of channel patterns;
a shield conductive layer arranged below the plurality of bit lines and extending in the vertical direction between the bit lines;
a shield contact connected to the shield conductive layer;
a cover insulating layer arranged between the plurality of bit lines and the shield conductive layer; and
a plurality of capacitor structures including a plurality of lower electrodes electrically connected to the plurality of channel patterns, an upper electrode on the plurality of lower electrodes, and a capacitor dielectric layer arranged between the plurality of lower electrodes and the upper electrode,
wherein the shield conductive layer comprises a main body unit having a rectangular shape in a plan view, and a pad unit having a rectangular shape and extending from corner portions of the main body unit, and including the shield contact arranged on the shield conductive layer.

12. The semiconductor memory device of claim 11,
wherein in a plan view the plurality of bit lines and the plurality of word lines overlap the main body unit in a vertical direction, and
the plurality of bit lines and the plurality of word lines do not overlap the pad unit in the vertical direction.

13. The semiconductor memory device of claim 11,
wherein each of the pad units extend from four corners of the main body unit in a plan view, each of the pad units have a smaller area than the main body unit, and a number of the pad units is four.

14. The semiconductor memory device of claim 13,
wherein one end of each of the plurality of bit lines is aligned in the first horizontal direction with one edge of the pad unit opposite to the main body unit and extending in the first horizontal direction among four edges of each of two pad units among four pad units, and
wherein another end of each of the plurality of bit lines is aligned in the first horizontal direction with one edge of the pad unit opposite to the main body unit and extending in the first horizontal direction among four edges of each of the other two pad units among the four pad units.

15. The semiconductor memory device of claim 13,
wherein one end of each of the plurality of word lines is aligned in the second horizontal direction with one edge of the pad unit opposite to the main body unit and extending in the second horizontal direction among four edges of each of two pad units among the four pad units, and
wherein another end of each of the plurality of bit lines is aligned in the second horizontal direction with one edge of the pad unit opposite to the main body unit and extending in the second horizontal direction among four edges of each of another two pad units among the four pad units.

16. The semiconductor memory device of claim 11, wherein the plurality of word lines and the plurality of back gate lines are alternately arranged in the second horizontal direction.

17. The semiconductor memory device of claim 11, wherein two word lines among the plurality of word lines and one back gate line among the plurality of back gate lines are alternately arranged in the second horizontal direction.

18. The semiconductor memory device of claim 11, wherein the plurality of word lines, the plurality of bit lines, and the plurality of channel patterns constitute a plurality of vertical channel transistors (VCT).

19. A semiconductor memory device comprising:
a periphery circuit structure including a plurality of periphery circuits;
on the periphery circuit structure, a plurality of word line structures including a plurality of word lines extending in a first horizontal direction and a plurality of gate insulating layers surrounding the plurality of word lines;
on the periphery circuit structure, a plurality of back gate structures including a plurality of back gate lines arranged apart from the plurality of word lines in a second horizontal direction different from the first horizontal direction and extending in the first horizontal direction, and a plurality of back gate insulating layers covering the plurality of back gate lines;
a plurality of channel patterns arranged in a row in the first horizontal direction and extending in a vertical direction;
the plurality of channel patterns arranged between a word line structure and a back gate line adjacent to each other in the second horizontal direction among the plurality of word line structures and the plurality of back gate structures;
a plurality of bit lines extending in the second horizontal direction and electrically connected to one end of the plurality of channel patterns;
the plurality of bit lines arranged below the plurality of word line structures, the plurality of back gate lines, and the plurality of channel patterns;
a shield conductive layer arranged below the plurality of bit lines and extending in the vertical direction between the bit lines;
an uppermost portion of the shield conductive layer arranged opposite to the plurality of channel patterns;
a shield contact connected to the shield conductive layer;
a cover insulating layer arranged between the plurality of bit lines and the shield conductive layer; and
a plurality of capacitor structures including a plurality of lower electrodes electrically connected to another end of the plurality of channel patterns in the vertical direction, an upper electrode on the plurality of lower electrodes, and a capacitor dielectric layer arranged between the plurality of lower electrodes and the upper electrode,
wherein the plurality of word lines, the plurality of bit lines, and the plurality of channel patterns constitute a plurality of vertical channel transistors, and
wherein the shield conductive layer comprises
a main body unit having a rectangular shape in a plan view,
the plurality of bit lines and the plurality of word lines overlapping the main body unit in the vertical direction, and
four pad units, each including the shield contact thereon and extending from an edge portion of the main body unit in a plan view, having a rectangular shape of less area than the main body unit, and not overlapping the plurality of bit lines and the plurality of word lines in the vertical direction.

20. The semiconductor memory device of claim 19,
wherein one end of each of the plurality of bit lines is aligned in the first horizontal direction with one edge of the pad unit opposite to the main body unit and extending in the first horizontal direction among four edges of each of two pad units among the four pad units,
wherein another end of each of the plurality of bit lines is aligned in the first horizontal direction with one edge of the pad unit opposite to the main body unit and extending in the first horizontal direction among four edges of each of the other two pad units among the four pad units,
wherein one end of each of the plurality of word lines is aligned in the second horizontal direction with one edge of the pad unit opposite to the main body unit and extending in the second horizontal direction among four edges of each of two pad units among the four pad units, and
wherein the other end of each of the plurality of word lines is aligned in the second horizontal direction with one edge of the pad unit opposite to the main body unit and extending in the second horizontal direction among four edges of each of other two pad units among the four pad units.
